(19) United States
(12) Patent Application Publication
(10) Pub. No.: US 2025/0286757 A1
(43) Pub. Date: Sep. 11, 2025

(54) PROBABILISTIC AMPLITUDE SHAPING INCLUDING ENERGY SELECTION, COMPOSITION DETERMINATION, AND AMPLITUDE SYMBOL SEQUENCE DETERMINATION

(71) Applicant: QUALCOMM Incorporated, San Diego, CA (US)

(72) Inventors: Wei LIU, Beijing (CN); Thomas Joseph RICHARDSON, South Orange, NJ (US); Liangming WU, Beijing (CN); Changlong XU, Beijing (CN); Ori SHENTAL, Marlboro, NJ (US); Hao XU, Beijing (CN)

(21) Appl. No.: 19/105,020

(22) PCT Filed: Sep. 1, 2022
(86) PCT No.: PCT/CN2022/116434

§ 371 Date: Feb. 19, 2025

(51) Int. Cl. H04L 25/03

(52) U.S. Cl. CPC H04L 25/03178; H04L 25/03343; H04L 2025/03611

(57) ABSTRACT

This disclosure provides methods, devices and systems for encoding data for wireless communication to achieve an amplitude distribution. One implementation includes a method in which probabilistic amplitude shaping is constrained by an energy value and a sequence composition. The implementation may include three phases. In a first phase, the energy value is determined. In a second phase, the sequence composition is determined. In a third phase, the output sequence is determined as constrained by the sequence composition. The methods generate output sequences defining amplitude symbols that are used to encode data for transmission.

### TECHNICAL FIELD

This disclosure relates generally to wireless communication, and more specifically, to encoding and decoding data to achieve an amplitude shaping of a transmitted or received signal.

### DESCRIPTION OF THE RELATED TECHNOLOGY

Wireless communications systems are widely deployed to provide various types of communication content such as voice, video, packet data, messaging, broadcast, and so on. These systems may be capable of supporting communication with multiple users by sharing the available system resources (e.g., time, frequency, and power). A wireless multiple-access communications system may include a number of base stations (BSs), each simultaneously supporting communications for multiple communication devices, which may be otherwise known as user equipment (UE).

To meet the growing demands for expanded mobile broadband connectivity, wireless communication technologies are advancing from the long term evolution (LTE) technology to a next generation new radio (NR) technology, which may be referred to as 5^{th} Generation (5G). For example, NR is designed to provide a lower latency, a higher bandwidth or a higher throughput, and a higher reliability than LTE. NR is designed to operate over a wide array of spectrum bands, for example, from low-frequency bands below about 1 gigahertz (GHz) and mid-frequency bands from about 1 GHz to about 6 GHz, to high-frequency bands such as millimeter wave (mmWave) bands. NR is also designed to operate across different spectrum types, from licensed spectrum to unlicensed and shared spectrum. Furthermore, as wireless communication becomes cheaper and more reliable, expectations among consumers change.

Transmitting and receiving devices may support the use of various modulation and coding schemes (MCSs) to transmit and receive data so as to optimally take advantage of wireless channel conditions, for example, to increase throughput, reduce latency, or enforce various quality of service (QpS) parameters. For example, existing technology supports the use of up to 1024-QAM and it is expected that 4096-QAM (also referred to as “4k QAM”) will also be implemented.

As communication protocols get more complex, there is a need in the art for encoding and decoding schemes that are efficient in terms of processing, storage, and energy use.

### SUMMARY

The following summarizes some aspects of the present disclosure to provide a basic understanding of the discussed technology. This summary is not an extensive overview of all contemplated features of the disclosure and is intended neither to identify key or critical elements of all aspects of the disclosure nor to delineate the scope of any or all aspects of the disclosure. Its sole purpose is to present some concepts of one or more aspects of the disclosure in summary form as a prelude to the more detailed description that is presented later.

One aspect includes a method of wireless communication, including generating a plurality (k) of information bits, where k is an integer greater than 1. The method also includes performing an encoding operation on the plurality of information bits, the encoding operation including: accessing a first plurality of cumulative sequence quantities, each cumulative sequence quantity of the first plurality of cumulative sequence quantities representing a quantity of symbol sequences of a length (n) and having at most a respective energy level; processing the first plurality of cumulative sequence quantities, including selecting a first energy level based at least in part on the plurality of information bits and the first plurality of cumulative sequence quantities; determining a composition of an output symbol sequence from among a first set of symbol sequences having the first energy level, including performing a plurality of iterations to identify a plurality of elements of the composition, a quantity of the plurality of iterations being related to a size of a symbol alphabet; and determining the output symbol sequence, including determining a plurality (n) of amplitude symbols of the output symbol sequence based at least in part on the composition and the plurality of information bits, wherein n is an integer greater than 1. The method also includes transmitting a wireless packet to at least one receiving device based on the output symbol sequence.

Another aspect includes a wireless communication device having at least one modem. The device also includes at least one processor communicatively coupled with the at least one modem. The device also includes at least one memory communicatively coupled with the at least one processor and storing processor-readable code that, when executed by the at least one processor in conjunction with the at least one modem, is configured to: generate a plurality of information bits; access a first plurality of cumulative sequence quantities, each cumulative sequence quantity of the first plurality of cumulative sequence quantities representing a quantity of symbol sequences of a length (n) and having at most a respective energy level; process the first plurality of cumulative sequence quantities, including selecting a first energy level based at least in part on the plurality of information bits and the first plurality of cumulative sequence quantities; determine a composition of an output symbol sequence from among a first set of symbol sequences having the first energy level, including performing a plurality of iterations to identify a plurality of elements of the composition, a quantity of the plurality of iterations being related to a size of a symbol alphabet; and determine the output symbol sequence, including determining a plurality (n) of amplitude symbols of the output symbol sequence based at least in part on the composition and the plurality of information bits; and transmit a wireless packet to at least one receiving device based on the output symbol sequence.

Another aspect includes a non-transitory computer-readable medium having program code recorded thereon for wireless communication by a wireless communication device. The non-transitory computer-readable medium includes code for generating a plurality of information bits. The medium also includes code for selecting a first energy level based at least in part on the plurality of information bits. The medium also includes code for determining a composition of an output symbol sequence from among a first set of symbol sequences having the first energy level, including performing a plurality of iterations to identify a plurality of elements of the composition, a quantity of the plurality of iterations being related to a size of a symbol alphabet. The medium also includes code for determining a plurality of amplitude symbols of the output symbol sequence based at least in part on the composition and the plurality of information bits. The medium also includes code for transmitting a wireless packet to at least one receiving device based on the output symbol sequence.

Another aspect includes a wireless communication device configured to encode a plurality (k) of information bits. The wireless communication device includes means for accessing a first plurality of cumulative sequence quantities, each cumulative sequence quantity of the first plurality of cumulative sequence quantities representing a quantity of symbol sequences of a length (n) and having at most a respective energy level; means for selecting a first energy level based at least in part on the plurality of information bits and the first plurality of cumulative sequence quantities; means for determining a composition of an output symbol sequence from among a first set of symbol sequences having the first energy level, including; means for determining a plurality (n) of amplitude symbols of the output symbol sequence based at least in part on the composition and the plurality of information bits; and means for transmitting a wireless packet to at least one receiving device based on the output symbol sequence.

### BRIEF DESCRIPTION OF THE DRAWINGS

FIG. 1 shows a pictorial diagram of an example wireless communication network.

FIG. 2 shows a block diagram of an example wireless communication.

FIG. 3 shows a diagram of an example base station.

FIG. 4 shows a diagram of an example user equipment.

FIG. 5 shows an example transmitter chain and an example receiver chain of an architecture for probabilistic amplitude shaping (PAS).

FIG. 6 is an illustration of a first phase of a three-phase AC encoding method, according to one implementation.

FIG. 7 is an illustration of Phases 1 and 2 of the three-phase AC encoding method, shown with respect to subintervals, according to one implementation.

FIG. 8 provides an illustration of a first iteration Phase 2 of the three-phase AC encoding method, according to one implementation.

FIG. 9 is an illustration of encoding in Phase 2 of the three-phase AC encoding method, using interval scaling, according to one implementation.

FIGS. 10A and 10B present an illustration of an example method for three-phase AC encoding, according to one implementation.

Like reference numbers and designations in the various drawings indicate like elements.

### DETAILED DESCRIPTION

The following description is directed to some particular implementations for the purposes of describing innovative aspects of this disclosure. However, a person having ordinary skill in the art will readily recognize that the teachings herein can be applied in a multitude of different ways. This disclosure relates generally to wireless communications systems, also referred to as wireless communications networks. In various aspects, the techniques and apparatus may be used for wireless communication networks such as code division multiple access (CDMA) networks, time division multiple access (TDMA) networks, frequency division multiple access (FDMA) networks, orthogonal FDMA (OFDMA) networks, single-carrier FDMA (SC-FDMA) networks, LTE networks, Global System for Mobile Communications (GSM) networks, 5^{th} Generation (5G) or new radio (NR) networks, Institute of Electrical and Electronics Engineers (IEEE) 802.11 standards, as well as other communications networks. As described herein, the terms “networks” and “systems” may be used interchangeably.

In current wireless communication systems, higher-order modulation (e.g., 16 QAM, 64 QAM and 256 QAM) are used. The constellations in these systems are fixed and each constellation point is used with equal probability. Over an additive white Gaussian noise (AWGN) channel, the capacity is achievable if the input distribution is a Gaussian distribution. A difference between the signal-to-noise (SNR) to achieve a rate with a given coding and modulation scheme and the SNR at which an optimal capacity-achieving scheme could operate at the same rate is referred to as the shaping gap. For an AWGN channel, the shaping gap can be asymptotically equal to about 1.53 dB when the channel inputs are uniformly distributed. Existing techniques to reduce or close the shaping gap include geometric shaping and probabilistic shaping. Geometric shaping implements equiprobable signaling with Gaussian-like distributed constellation points. Probabilistic shaping employs equidistant constellation points and implements non-uniform (e.g., Gaussian-like) signal distribution.

Traditional approaches to probabilistic shaping include trellis shaping and shell mapping. Probabilistic amplitude shaping (PAS) is another technique to perform probabilistic shaping, and it may combine an outer layer of shaping with an inner layer of binary forward-error-correction (FEC) so that it can provide a low-complexity and flexible integration with existing bit-interleaved coded modulation (BICM) schemes. A PAS scheme may implement amplitude-shift keying (ASK) constellations, e.g., by providing quadrature amplitude modulation (QAM) constellations by mapping two ASK symbols to one QAM symbol. PAS may provide large shaping gain and inherent rate adaptation functionality.

This disclosure provides methods, devices, and systems for encoding data for wireless communication to achieve a desired amplitude distribution. A proposed arithmetic coding (AC) encoding may be used to perform distribution matching in a PAS scheme. One example includes a three-phase AC encoding method. In a first phase of the method, a wireless communication device determines an energy of an output sequence, such as by accessing a plurality of cumulative sequence quantities and then applying transition probabilities to those cumulative sequence quantities. The energy of the output sequence may be selected by applying a binary expansion of input bits to the transition probabilities. The second phase may include multiple iterations to determine a composition of the output sequence. The second phase is constrained by the energy from the first phase, and the plurality of iterations are performed one iteration per composition element. At the beginning of the third phase, the composition of the output sequence has been determined, but the ordering of amplitude symbols within the output sequence has not yet been determined. The third phase may use a multitude of further iterations, such as n iterations to determine an order of n amplitude symbols in the output sequence. The output sequence may then be used to transmit data. A proposed AC decoding can be used to perform distribution dematching in a PAS scheme.

Various implementations can be viewed as an efficient method to realize distribution matching and dematching. For instance, the various implementations may be more energy efficient by using energy as a constraint. Furthermore, the calculations of the first phase and second phase may reduce computing burden for calculations of the third phase, thereby reducing computing burden and power use overall.

An OFDMA network may implement a radio technology such as evolved UTRA (E-UTRA), Institute of Electrical and Electronics Engineers (IEEE) 802.11, IEEE 802.16, IEEE 802.20, flash-OFDM and the like. UTRA, E-UTRA, and GSM are part of universal mobile telecommunication system (UMTS). In particular, long term evolution (LTE) is a release of UMTS that uses E-UTRA. UTRA, E-UTRA, GSM, UMTS and LTE are described in documents provided from an organization named “3rd Generation Partnership Project” (3GPP), and cdma2000 is described in documents from an organization named “3rd Generation Partnership Project 2” (3GPP2). These various radio technologies and standards are known or are being developed. For example, the 3rd Generation Partnership Project (3GPP) is a collaboration between groups of telecommunications associations that aims to define a globally applicable third generation (3G) mobile phone specification. 3GPP long term evolution (LTE) is a 3GPP project which was aimed at improving the UMTS mobile phone standard. The 3GPP may define specifications for the next generation of mobile networks, mobile systems, and mobile devices. The present disclosure is concerned with the evolution of wireless technologies from LTE, 4G, 5G, NR, and beyond with shared access to wireless spectrum between networks using a collection of new and different radio access technologies or radio air interfaces.

In particular, 5G networks contemplate diverse deployments, diverse spectrum, and diverse services and devices that may be implemented using an OFDM-based unified, air interface. To achieve these goals, further enhancements to LTE and LTE-A are considered in addition to development of the new radio technology for 5G NR networks. The 5G NR will be capable of scaling to provide coverage (1) to a massive Internet of things (IoTs) with a ULtra-high density (e.g., ˜1M nodes/km²), ultra-low complexity (e.g., ˜10 s of bits/sec), ultra-low energy (e.g., ˜10+ years of battery life), and deep coverage with the capability to reach challenging locations; (2) including mission-critical control with strong security to safeguard sensitive personal, financial, or classified information, ultra-high reliability (e.g., ˜99.9999% reliability), ultra-low latency (e.g., ˜1 ms), and users with wide ranges of mobility or lack thereof; and (3) with enhanced mobile broadband including extreme high capacity (e.g., ˜10 Tbps/km²), extreme data rates (e.g., multi-Gbps rate, 100+ Mbps user experienced rates), and deep awareness with advanced discovery and optimizations.

A 5G NR system may be implemented to use optimized OFDM-based waveforms with scalable numerology and transmission time interval (TTI); having a common, flexible framework to efficiently multiplex services and features with a dynamic, low-latency time division duplex (TDD)/frequency division duplex (FDD) design; and with advanced wireless technologies, such as massive multiple input, multiple output (MIMO), robust millimeter wave (mmWave) transmissions, advanced channel coding, and device-centric mobility. Scalability of the numerology in 5G NR, with scaling of subcarrier spacing, may efficiently address operating diverse services across diverse spectrum and diverse deployments. For example, in various outdoor and macro coverage deployments of less than 3GHz FDD/TDD implementations, subcarrier spacing may occur with 15 kHz, for example over 5, 10, 20 MHz, and the like bandwidth (BW). For other various outdoor and small cell coverage deployments of TDD greater than 3 GHz, subcarrier spacing may occur with 30 kHz over 80/100 MHz BW. For other various indoor wideband implementations, using a TDD over the unlicensed portion of the 5 GHz band, the subcarrier spacing may occur with 60 kHz over a 160 MHz BW. Finally, for various deployments transmitting with mmWave components at a TDD of 28 GHz, subcarrier spacing may occur with 120 kHz over a 500 MHz BW. In certain aspects, frequency bands for 5G NR are separated into two different frequency ranges, a frequency range one (FR1) and a frequency range two (FR2). FR1 bands include frequency bands at 7 GHz or lower (e.g., between about 410 MHz to about 7125 MHz). FR2 bands include frequency bands in mmWave ranges between about 24.25 GHz and about 52.6 GHz. The mmWave bands may have a shorter range, but a higher bandwidth than the FR1 bands. Additionally, 5G NR may support different sets of subcarrier spacing for different frequency ranges.

The scalable numerology of the 5G NR facilitates scalable TTI for diverse latency and quality of service (QoS) requirements. For example, shorter TTI may be used for low latency and high reliability, while longer TTI may be used for higher spectral efficiency. The efficient multiplexing of long and short TTIs to allow transmissions to start on symbol boundaries. 5G NR also contemplates a self-contained integrated subframe design with UL/downlink scheduling information, data, and acknowledgement in the same subframe. The self-contained integrated subframe supports communications in unlicensed or contention-based shared spectrum, adaptive UL/downlink that may be flexibly configured on a per-cell basis to dynamically switch between UL and downlink to meet the current traffic needs

Various other aspects and features of the disclosure are further described below. It should be apparent that the teachings herein may be embodied in a wide variety of forms and that any specific structure, function, or both being disclosed herein is merely representative and not limiting. Based on the teachings herein one of an ordinary level of skill in the art should appreciate that an aspect disclosed herein may be implemented independently of any other aspects and that two or more of these aspects may be combined in various ways. For example, an apparatus may be implemented or a method may be practiced using any number of the aspects set forth herein. In addition, such an apparatus may be implemented or such a method may be practiced using other structure, functionality, or structure and functionality in addition to or other than one or more of the aspects set forth herein. For example, a method may be implemented as part of a system, device, apparatus, and/or as instructions stored on a computer readable medium for execution on a processor or computer. Furthermore, an aspect may comprise at least one element of a claim.

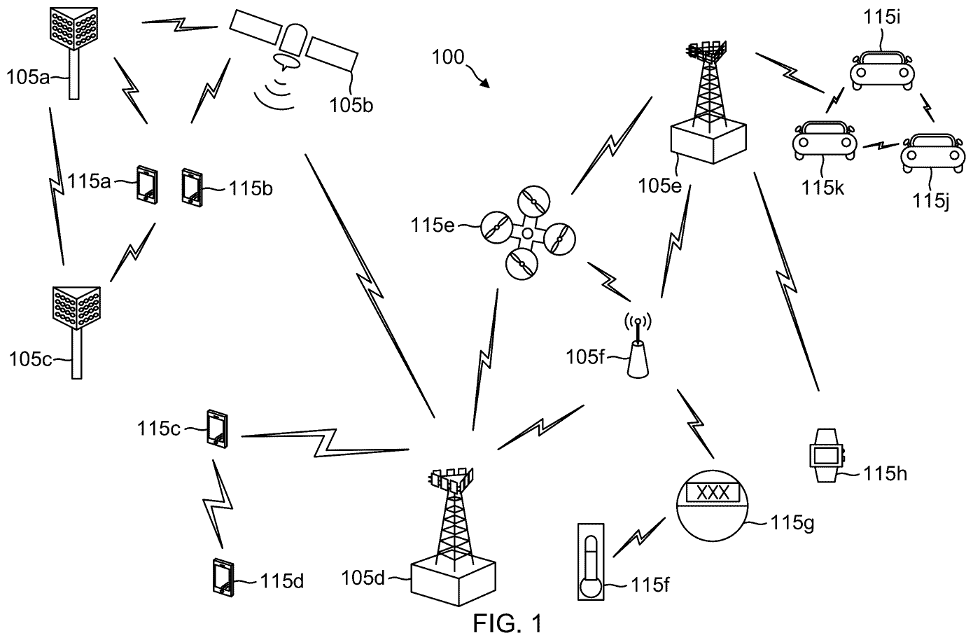

FIG. 1 illustrates a wireless communication network 100 according to some aspects of the present disclosure. The network 100 may be a 5G network. The network 100 includes a number of base stations (BSs) 105 (individually labeled as 105a, 105b, 105c, 105d, 105e, and 105f) and other network entities. A BS 105 may be a station that communicates with UEs 115 (individually labeled as 115a, 115b, 115c, 115d, 115e, 115f, 115g, 115h, and 115k) and may also be referred to as an evolved node B (eNB), a next generation eNB (gNB), an access point, and the like. Each BS 105 may provide communication coverage for a particular geographic area. In 3GPP, the term “cell” can refer to this particular geographic coverage area of a BS 105 and/or a BS subsystem serving the coverage area, depending on the context in which the term is used.

A BS 105 may provide communication coverage for a macro cell or a small cell, such as a pico cell or a femto cell, and/or other types of cell. A macro cell generally covers a relatively large geographic area (e.g., several kilometers in radius) and may allow unrestricted access by UEs with service subscriptions with the network provider. A small cell, such as a pico cell, would generally cover a relatively smaller geographic area and may allow unrestricted access by UEs with service subscriptions with the network provider. A small cell, such as a femto cell, would also generally cover a relatively small geographic area (e.g., a home) and, in addition to unrestricted access, may also provide restricted access by UEs having an association with the femto cell (e.g., UEs in a closed subscriber group (CSG), UEs for users in the home, and the like). A BS for a macro cell may be referred to as a macro BS. A BS for a small cell may be referred to as a small cell BS, a pico BS, a femto BS or a home BS. In the example shown in FIG. 1, the BSs 105d and 105e may be regular macro BSs, while the BSs 105a-105c may be macro BSs enabled with one of three dimension (3D), full dimension (FD), or massive MIMO. The BSs 105a-105c may take advantage of their higher dimension MIMO capabilities to exploit 3D beamforming in both elevation and azimuth beamforming to increase coverage and capacity. The BS 105f may be a small cell BS which may be a home node or portable access point. A BS 105 may support one or multiple (e.g., two, three, four, and the like) cells.

The network 100 may support synchronous or asynchronous operation. For synchronous operation, the BSs may have similar frame timing, and transmissions from different BSs may be approximately aligned in time. For asynchronous operation, the BSs may have different frame timing, and transmissions from different BSs may not be aligned in time.

The UEs 115 are dispersed throughout the wireless network 100, and each UE 115 may be stationary or mobile. A UE 115 may also be referred to as a terminal, a mobile station, a subscriber unit, a station, or the like. A UE 115 may be a cellular phone, a personal digital assistant (PDA), a wireless modem, a wireless communication device, a handheld device, a tablet computer, a laptop computer, a cordless phone, a wireless local loop (WLL) station, or the like. In one aspect, a UE 115 may be a device that includes a Universal Integrated Circuit Card (UICC). In another aspect, a UE may be a device that does not include a UICC. In some aspects, the UEs 115 that do not include UICCs may also be referred to as IoT devices or internet of everything (IoE) devices. The UEs 115a-115d are examples of mobile smart phone-type devices accessing network 100. A UE 115 may also be a machine specifically configured for connected communication, including machine type communication (MTC), enhanced MTC (eMTC), narrowband IoT (NB-IoT) and the like. The UEs 115e-115h are examples of various machines configured for communication that access the network 100. The UEs 115i-115k are examples of vehicles equipped with wireless communication devices configured for communication that access the network 100. A UE 115 may be able to communicate with any type of the BSs, whether macro BS, small cell, or the like. In FIG. 1, a lightning bolt (e.g., communication links) indicates wireless transmissions between a UE 115 and a serving BS 105, which is a BS designated to serve the UE 115 on the downlink (DL) and/or uplink (UL), desired transmission between BSs 105, backhaul transmissions between BSs, or sidelink transmissions between UEs 115.

In operation, the BSs 105a-105c may serve the UEs 115a and 115b using 3D beamforming and coordinated spatial techniques, such as coordinated multipoint (CoMP) or multi-connectivity. The macro BS 105d may perform backhaul communications with the BSs 105a-105c, as well as small cell, the BS 105f. The macro BS 105d may also transmits multicast services which are subscribed to and received by the UEs 115c and 115d. Such multicast services may include mobile television or stream video, or may include other services for providing community information, such as weather emergencies or alerts, such as Amber alerts or gray alerts.

The BSs 105 may also communicate with a core network. The core network may provide user authentication, access authorization, tracking, Internet Protocol (IP) connectivity, and other access, routing, or mobility functions. At least some of the BSs 105 (e.g., which may be an example of a gNB or an access node controller (ANC)) may interface with the core network through backhaul links (e.g., NG-C, NG-U, etc.) and may perform radio configuration and scheduling for communication with the UEs 115. In various examples, the BSs 105 may communicate, either directly or indirectly (e.g., through core network), with each other over backhaul links (e.g., X1, X2, etc.), which may be wired or wireless communication links.

The network 100 may also support communications with ultra-reliable and redundant links for devices, such as the UE 115e, which may be airborne. Redundant communication links with the UE 115e may include links from the macro BSs 105d and 105e, as well as links from the small cell BS 105f. Other machine type devices, such as the UE 115f (e.g., a thermometer), the UE 115g (e.g., smart meter), and UE 115h (e.g., wearable device) may communicate through the network 100 either directly with BSs, such as the small cell BS 105f, and the macro BS 105e, or in multi-action-size configurations by communicating with another user device which relays its information to the network, such as the UE 115f communicating temperature measurement information to the smart meter, the UE 115g, which is then reported to the network through the small cell BS 105f. The network 100 may also provide additional network efficiency through dynamic, low-latency TDD/FDD communications, such as V2V, V2X, C-V2X communications between a UE 115i, 115j, or 115k and other UEs 115, and/or vehicle-to-infrastructure (V2I) communications between a UE 115i, 115j, or 115k and a BS 105.

In some implementations, the network 100 utilizes OFDM-based waveforms for communications. An OFDM-based system may partition the system BW into multiple (K) orthogonal subcarriers, which are also commonly referred to as subcarriers, tones, bins, or the like. Each subcarrier may be modulated with data. In some aspects, the subcarrier spacing between adjacent subcarriers may be fixed, and the total number of subcarriers (K) may be dependent on the system BW. The system BW may also be partitioned into subbands. In other aspects, the subcarrier spacing and/or the duration of TTIs may be scalable.

In some aspects, the BSs 105 can assign or schedule transmission resources (e.g., in the form of time-frequency resource blocks (RB)) for downlink (DL) and uplink (UL) transmissions in the network 100. DL refers to the transmission direction from a BS 105 to a UE 115, whereas UL refers to the transmission direction from a UE 115 to a BS 105. The communication can be in the form of radio frames. A radio frame may be divided into a plurality of subframes or slots, for example, about 10. Each slot may be further divided into mini-slots. In a FDD mode, simultaneous UL and DL transmissions may occur in different frequency bands. For example, each subframe includes a UL subframe in a UL frequency band and a DL subframe in a DL frequency band. In a TDD mode, UL and DL transmissions occur at different time periods using the same frequency band. For example, a subset of the subframes (e.g., DL subframes) in a radio frame may be used for DL transmissions and another subset of the subframes (e.g., UL subframes) in the radio frame may be used for UL transmissions.

The DL subframes and the UL subframes can be further divided into several regions. For example, each DL or UL subframe may have pre-defined regions for transmissions of reference signals, control information, and data. Reference signals are predetermined signals that facilitate the communications between the BSs 105 and the UEs 115. For example, a reference signal can have a particular pilot pattern or structure, where pilot tones may span across an operational BW or frequency band, each positioned at a pre-defined time and a pre-defined frequency. For example, a BS 105 may transmit cell specific reference signals (CRSs) and/or channel state information-reference signals (CSI-RSs) to enable a UE 115 to estimate a DL channel. Similarly, a UE 115 may transmit sounding reference signals (SRSs) to enable a BS 105 to estimate a UL channel. Control information may include resource assignments and protocol controls. Data may include protocol data and/or operational data. In some aspects, the BSs 105 and the UEs 115 may communicate using self-contained subframes. A self-contained subframe may include a portion for DL communication and a portion for UL communication. A self-contained subframe can be DL-centric or UL-centric. A DL-centric subframe may include a longer duration for DL communication than for UL communication. A UL-centric subframe may include a longer duration for UL communication than for UL communication.

In some aspects, the network 100 may be an NR network deployed over a licensed spectrum. The BSs 105 can transmit synchronization signals (e.g., including a primary synchronization signal (PSS) and a secondary synchronization signal (SSS)) in the network 100 to facilitate synchronization. The BSs 105 can broadcast system information associated with the network 100 (e.g., including a master information block (MIB), remaining system information (RMSI), and other system information (OSI)) to facilitate initial network access. In some aspects, the BSs 105 may broadcast the PSS, the SSS, and/or the MIB in the form of SSBs and may broadcast the RMSI and/or the OSI over a physical downlink shared channel (PDSCH). The MIB may be transmitted over a physical broadcast channel (PBCH).

In some aspects, a UE 115 attempting to access the network 100 may perform an initial cell search by detecting a PSS from a BS 105. The PSS may enable synchronization of period timing and may indicate a physical layer identity value. The UE 115 may then receive a SSS. The SSS may enable radio frame synchronization, and may provide a cell identity value, which may be combined with the physical layer identity value to identify the cell. The PSS and the SSS may be located in a central portion of a carrier or any suitable frequencies within the carrier.

After receiving the PSS and SSS, the UE 115 may receive a MIB. The MIB may include system information for initial network access and scheduling information for RMSI and/or OSI. After decoding the MIB, the UE 115 may receive RMSI and/or OSI. The RMSI and/or OSI may include radio resource control (RRC) information related to random access channel (RACH) procedures, paging, control resource set (CORESET) for physical downlink control channel (PDCCH) monitoring, physical UL control channel (PUCCH), physical UL shared channel (PUSCH), power control, and SRS.

After obtaining the MIB, the RMSI and/or the OSI, the UE 115 can perform a random access procedure to establish a connection with the BS 105. In some examples, the random access procedure may be a four-step random access procedure. For example, the UE 115 may transmit a random access preamble and the BS 105 may respond with a random access response. The random access response (RAR) may include a detected random access preamble identifier (ID) corresponding to the random access preamble, timing advance (TA) information, a UL grant, a temporary cell-radio network temporary identifier (C-RNTI), and/or a backoff indicator. Upon receiving the random access response, the UE 115 may transmit a connection request to the BS 105 and the BS 105 may respond with a connection response. The connection response may indicate a contention resolution. In some examples, the random access preamble, the RAR, the connection request, and the connection response can be referred to as message 1 (MSG1), message 2 (MSG2), message 3 (MSG3), and message 4 (MSG4), respectively. In some examples, the random access procedure may be a two-step random access procedure, where the UE 115 may transmit a random access preamble and a connection request in a single transmission and the BS 105 may respond by transmitting a random access response and a connection response in a single transmission.

After establishing a connection, the UE 115 and the BS 105 can enter a normal operation stage, where operational data may be exchanged. For example, the BS 105 may schedule the UE 115 for UL and/or DL communications. The BS 105 may transmit UL and/or DL scheduling grants to the UE 115 via a PDCCH. The scheduling grants may be transmitted in the form of DL control information (DCI). The BS 105 may transmit a DL communication signal (e.g., carrying data) to the UE 115 via a PDSCH according to a DL scheduling grant. The UE 115 may transmit a UL communication signal to the BS 105 via a PUSCH and/or PUCCH according to a UL scheduling grant. The connection may be referred to as an RRC connection. When the UE 115 is actively exchanging data with the BS 105, the UE 115 is in an RRC connected state.

In an example, after establishing a connection with the BS 105, the UE 115 may initiate an initial network attachment procedure with the network 100. The BS 105 may coordinate with various network entities or fifth generation core (5GC) entities, such as an access and mobility function (AMF), a serving gateway (SGW), and/or a packet data network gateway (PGW), to complete the network attachment procedure.

In some aspects, the BS 105 may communicate with a UE 115 using HARQ techniques to improve communication reliability, for example, to provide a URLLC service. The BS 105 may schedule a UE 115 for a PDSCH communication by transmitting a DL grant in a PDCCH. The BS 105 may transmit a DL data packet to the UE 115 according to the schedule in the PDSCH. The DL data packet may be transmitted in the form of a transport block (TB). If the UE 115 receives the DL data packet successfully, the UE 115 may transmit a HARQ ACK to the BS 105. Conversely, if the UE 115 fails to receive the DL transmission successfully, the UE 115 may transmit a HARQ NACK to the BS 105. Upon receiving a HARQ NACK from the UE 115, the BS 105 may retransmit the DL data packet to the UE 115. The BS 105 and the UE 115 may also apply HARQ for UL communications using substantially similar mechanisms as the DL HARQ.

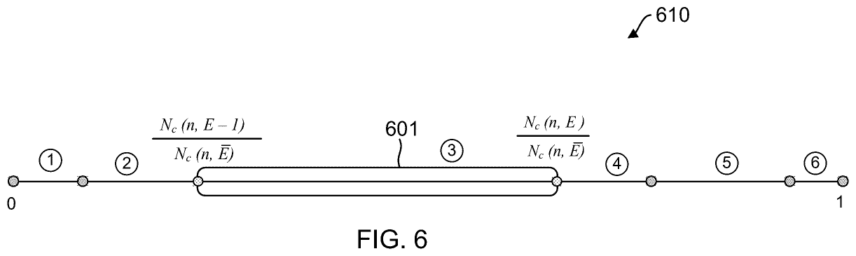

In some aspects, a UE 115 and a BS 105 may be capable of encoding and decoding information according to the three-phase AC encoding and decoding methods described herein, such as in FIGS. 6-10.

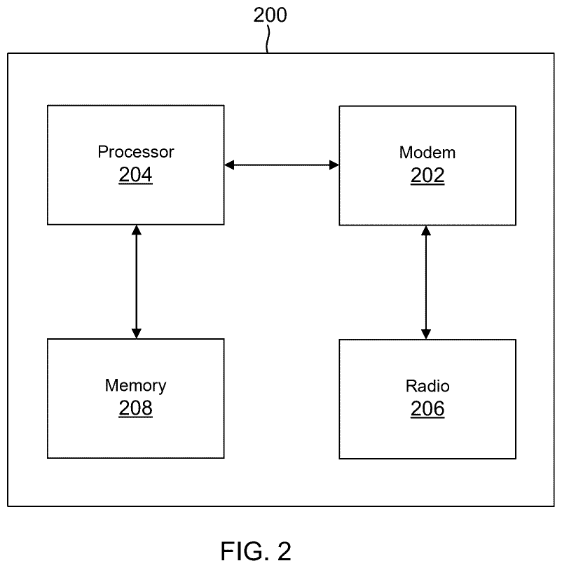

FIG. 2 shows a block diagram of an example wireless communication device 200. In some implementations, the wireless communication device 200 can be an example of a device for use in a UE such as one of the UEs 115 described above with reference to FIG. 1. In some implementations, the wireless communication device 200 can be an example of a device for use in a BS such as the BSs 105 described above with reference to FIG. 1. The wireless communication device 200 is capable of transmitting and receiving wireless communications in the form of, for example, wireless packets.

The wireless communication device 200 can be, or can include, a chip, system on chip (SoC), chipset, package or device that includes one or more modems 202, for example, a 3GPP 4G LTE or 5G compliant modem. In some implementations, the one or more modems 202 (collectively “the modem 202”) additionally include a Wi-Fi (IEEE 802.11 compliant) modem. In some implementations, the wireless communication device 200 also includes one or more processors, processing blocks or processing elements 204 (collectively “the processor 204”) coupled with the modem 202. In some implementations, the wireless communication device 200 additionally includes one or more radios 206 (collectively “the radio 206”) coupled with the modem 202. In some implementations, the wireless communication device 200 further includes one or more memory blocks or elements 208 (collectively “the memory 208”) coupled with the processor 204 or the modem 202.

The modem 202 can include an intelligent hardware block or device such as, for example, an application-specific integrated circuit (ASIC), among other examples. The modem 202 is generally configured to implement a PHY layer, and in some implementations, also a portion of a MAC layer (for example, a hardware portion of the MAC layer). For example, the modem 202 is configured to modulate packets and to output the modulated packets to the radio 206 for transmission over the wireless medium. The modem 202 is similarly configured to obtain modulated packets received by the radio 206 and to demodulate the packets to provide demodulated packets. In addition to a modulator and a demodulator, the modem 202 may further include digital signal processing (DSP) circuitry, automatic gain control (AGC) circuitry, a coder, a decoder, a multiplexer and a demultiplexer. For example, while in a transmission mode, data obtained from the processor 204 may be provided to an encoder, which encodes the data to provide coded bits. The coded bits may then be mapped to a number N_{SS} of spatial streams for spatial multiplexing or a number N_{STS} of space-time streams for space-time block coding (STBC). The coded bits in the streams may then be mapped to points in a modulation constellation (using a selected MCS) to provide modulated symbols. The modulated symbols in the respective spatial or space-time streams may be multiplexed, transformed via an inverse fast Fourier transform (IFFT) block, and subsequently provided to the DSP circuitry (for example, for Tx windowing and filtering). The digital signals may then be provided to a digital-to-analog converter (DAC). The resultant analog signals may then be provided to a frequency upconverter, and ultimately, the radio 206. In implementations involving beamforming, the modulated symbols in the respective spatial streams are precoded via a steering matrix prior to their provision to the IFFT block.

While in a reception mode, the DSP circuitry is configured to acquire a signal including modulated symbols received from the radio 206, for example, by detecting the presence of the signal and estimating the initial timing and frequency offsets. The DSP circuitry is further configured to digitally condition the signal, for example, using channel (narrowband) filtering and analog impairment conditioning (such as correcting for I/Q imbalance), and by applying digital gain to ultimately obtain a narrowband signal. The output of the DSP circuitry may then be fed to the AGC, which is configured to use information extracted from the digital signals, for example, in one or more received training fields, to determine an appropriate gain. The output of the DSP circuitry also is coupled with a demultiplexer that demultiplexes the modulated symbols when multiple spatial streams or space-time streams are received. The demultiplexed symbols may be provided to a demodulator, which is configured to extract the symbols from the signal and, for example, compute the logarithm likelihood ratios (LLRs) for each bit position of each subcarrier in each spatial stream. The demodulator is coupled with the decoder, which may be configured to process the LLRs to provide decoded bits. The decoded bits may then be provided to the MAC layer (the processor 204) for processing, evaluation or interpretation.

The radio 206 generally includes at least one radio frequency (RF) transmitter (or “transmitter chain”) and at least one RF receiver (or “receiver chain”), which may be combined into one or more transceivers. For example, each of the RF transmitters and receivers may include various analog circuitry including at least one power amplifier (PA) and at least one low-noise amplifier (LNA), respectively. The RF transmitters and receivers may, in turn, be coupled to one or more antennas. For example, in some implementations, the wireless communication device 200 can include, or be coupled with, multiple transmit antennas (each with a corresponding transmit chain) and multiple receive antennas (each with a corresponding receive chain). The symbols output from the modem 202 are provided to the radio 206, which then transmits the symbols via the coupled antennas. Similarly, symbols received via the antennas are obtained by the radio 206, which then provides the symbols to the modem 202.

The processor 204 can include an intelligent hardware block or device such as, for example, a processing core, a processing block, a central processing unit (CPU), a microprocessor, a microcontroller, a digital signal processor (DSP), an application-specific integrated circuit (ASIC), a programmable logic device (PLD) such as a field programmable gate array (FPGA), discrete gate or transistor logic, discrete hardware components, or any combination thereof designed to perform the functions described herein. The processor 204 processes information received through the radio 206 and the modem 202, and processes information to be output through the modem 202 and the radio 206 for transmission through the wireless medium. For example, the processor 204 may implement a control plane and at least a portion of a MAC layer configured to perform various operations related to the generation, transmission, reception and processing of packets. In some implementations, the MAC layer is configured to generate packets for provision to the PHY layer for coding, and to receive decoded information bits from the PHY layer for processing as packets. The MAC layer may further be configured to allocate time and frequency resources, for example, for OFDMA, among other operations or techniques. In some implementations, the processor 204 may generally control the modem 202 to cause the modem to perform various operations described above.

The memory 208 can include tangible storage media such as random-access memory (RAM) or read-only memory (ROM), or combinations thereof. The memory 208 also can store non-transitory processor-or computer-executable software (SW) code containing instructions that, when executed by the processor 204, cause the processor to perform various operations described herein for wireless communication, including the generation, transmission, reception and interpretation of frames or packets. For example, various functions of components disclosed herein, or various blocks or steps of a method, operation, process or algorithm disclosed herein, can be implemented as one or more modules of one or more computer programs.

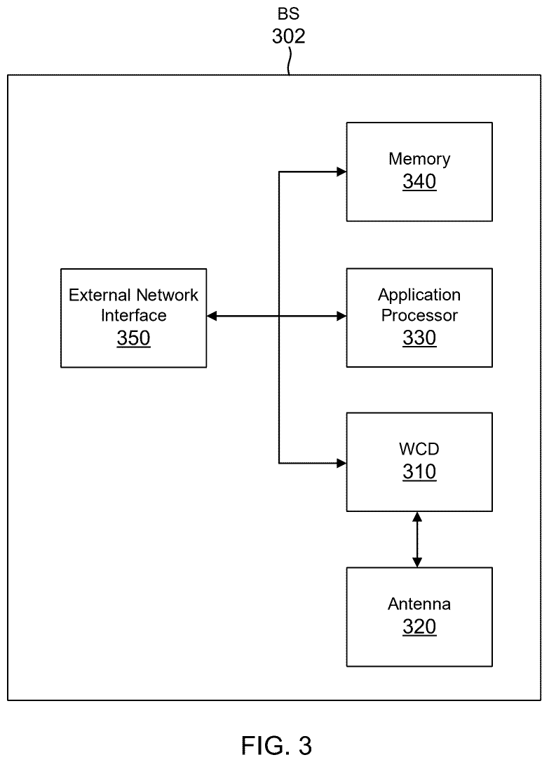

FIG. 3 shows a block diagram of an example BS 302. For example, the BS 302 can be an example implementation of the BS 105 described with reference to FIG. 1. The BS 302 includes a wireless communication device (WCD) 310 (although the BS 302 may itself also be referred to generally as a wireless communication device as used herein). For example, the wireless communication device 310 may be an example implementation of the wireless communication device 200 described with reference to FIG. 2. The BS 302 also includes multiple antennas 320 coupled with the wireless communication device 310 to transmit and receive wireless communications. In some implementations, the BS 302 additionally includes an application processor 330 coupled with the wireless communication device 310, and a memory 340 coupled with the application processor 330. The BS 302 further includes at least one external network interface 350 that enables the BS 302 to communicate with a core network or backhaul network to gain access to external networks including the Internet. For example, the external network interface 350 may include one or both of a wired (for example, Ethernet) network interface and a wireless network interface. Ones of the aforementioned components can communicate with other ones of the components directly or indirectly, over at least one bus. The BS 302 further includes a housing that encompasses the wireless communication device 310, the application processor 330, the memory 340, and at least portions of the antennas 320 and external network interface 350.

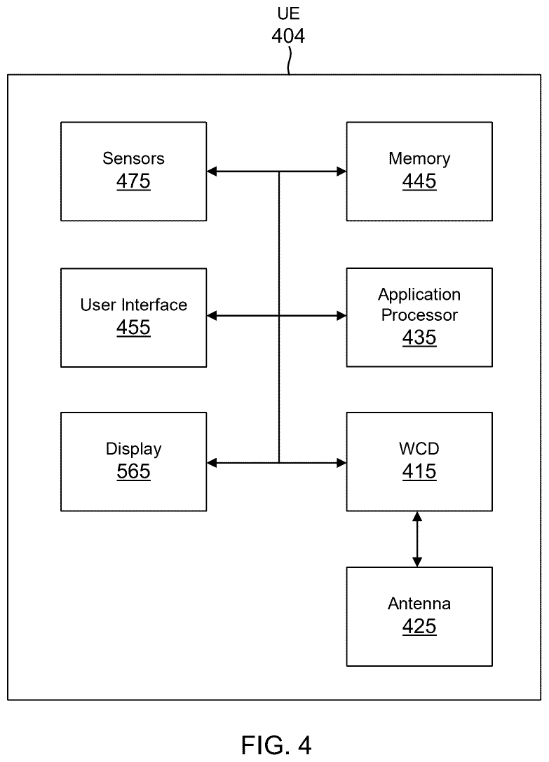

FIG. 4 shows a block diagram of an example UE 304. For example, the UE 304 can be an example implementation of the UE 115 described with reference to FIG. 1. The UE 304 includes a wireless communication device 415 (although the UE 304 may itself also be referred to generally as a wireless communication device as used herein). For example, the wireless communication device 415 may be an example implementation of the wireless communication device 200 described with reference to FIG. 2. The UE 304 also includes one or more antennas 425 coupled with the wireless communication device 415 to transmit and receive wireless communications. The UE 304 additionally includes an application processor 435 coupled with the wireless communication device 415, and a memory 445 coupled with the application processor 435. In some implementations, the UE 304 further includes a user interface (UI) 455 (such as a touchscreen or keypad) and a display 465, which may be integrated with the UI 455 to form a touchscreen display. In some implementations, the UE 304 may further include one or more sensors 475 such as, for example, one or more inertial sensors, accelerometers, temperature sensors, pressure sensors, or altitude sensors. Ones of the aforementioned components can communicate with other ones of the components directly or indirectly, over at least one bus. The UE 304 further includes a housing that encompasses the wireless communication device 415, the application processor 435, the memory 445, and at least portions of the antennas 425, UI 455, and display 465.

### General Context for Probabilistic Amplitude Shaping

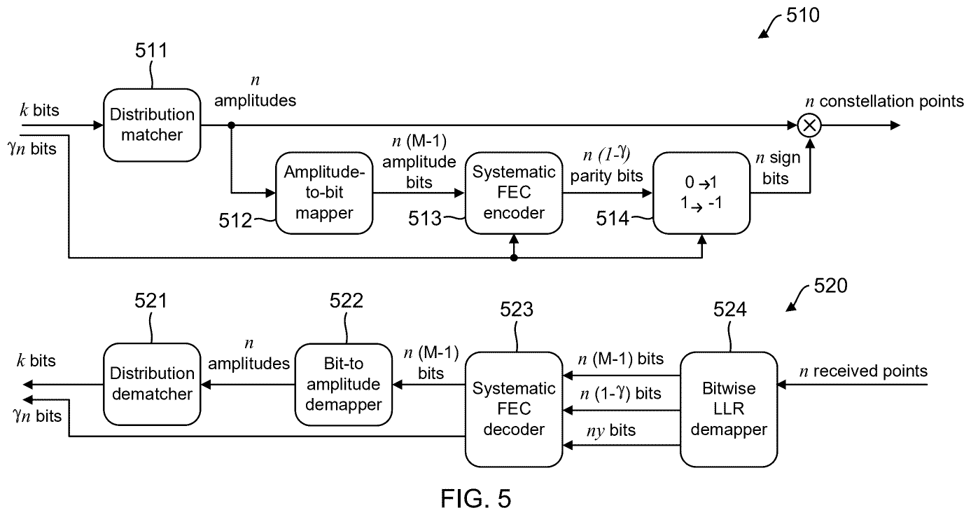

FIG. 5 illustrates an example transmitter chain 510 and an example receiver chain 520 of an architecture for probabilistic amplitude shaping (PAS), according to one implementation. For instance, the transmitter chain 510 and the receiver chain 520 may be implemented within the wireless communication device 200 of FIG. 2. The transmitter chain 510 includes a distribution matcher 511 as well as a forward-error-correction (FEC) chain having mapper 512, FEC encoder 513, and sign module 514. The three-phase AC encoding and decoding methods discussed herein may be implemented by a device conforming to the architecture of FIG. 5, though the scope of implementation is not limited to that architecture. Encoding methods disclosed herein can be used to perform a distribution matching task (e.g., at the distribution matcher 511) in that system, and decoding methods disclosed herein can be used to perform a distribution dematching task (e.g., at the distribution dematcher 521).

The receiver chain 520 includes a distribution dematcher 521, a demapper 522, FEC decoder 523, and bitwise logarithm likelihood ratio (LLR) demapper 524. Example implementations provide three-phase AC encoding and three-phase AC decoding methods. In some examples, the three-phase AC encoding methods may be performed using the distribution matcher 511, and the three-phase AC decoding methods may be performed using the distribution dematcher 521.

The example of FIG. 5 uses 2^{M}-ary amplitude shifting keying (ASK) constellation {±1, ±3, . . . , ±(2^{M-1})} with amplitude alphabet [symbol] ={1,3, . . . , 2^{M}−1}. The n(M−1) amplitude bits and the γn information bits together constitute the n(M−1+γ) bits as input to the systematic FEC encoder 513, which then generates n(1−γ) parity bits. The n(1−γ) parity bits together with the γn information bits are converted to n sign bits and are pointwise multiplied with the n amplitudes from the output of the distribution matcher 511. The distribution matching (DM) rate is R_{dm}=k/n, the systematic forward-error-correction (FEC) code rate is R_{c}=(M−1+γ)/M, and the transmission rate is Rₜ=R_{dm}+γ, where γn is a number of additional information bits added for FEC.

The present example uses a fixed-to-fixed DM at the distribution matcher 511 to map a length-k bit sequence to a length-n amplitude sequence, and it induces a non-uniform marginal distribution over the amplitude symbols {1, 3, . . . , 2^{M-}1}. The k bits are typically assumed to be independent and identically distributed (i.i.d.) with the uniform distribution. However, the non-uniform distribution over the amplitude symbols is expected to be closer to the capacity-achieving distribution than the uniform one, e.g., being more Gaussian-like or being a Maxwell-Boltzmann distribution in the AWGN setting.

### Symbol Terminologies and Nomenclatures

Before getting into examples of arithmetic coding (AC) being performed, it is instructive to look at mathematical functions that may be applied to data for the purpose of transmitting and receiving encoded data. The following paragraphs introduce concepts that underpin the three-phase AC encoding and decoding methods described with respect to FIGS. 6-10.

For example, an alphabet may define possible amplitude symbols, and it may be given the symbolic notation [symbol] ₘ. For example, if m>1 is an integer, then [symbol] m={a₁, a₂, . . . , aₘ} is a symbol alphabet of size m. Examples impose an ordering < on the alphabet [symbol] m such that aᵢ<aᵢ₊₁ for each i, i.e., a₁<a₂<· · · <aₘ. For a given m and for each integer t between 1 and m, [symbol] ₜ is the subset of [symbol] ₘ consisting of symbol aᵢ for all i≤t. In other words, [symbol] ₜ={aᵢ∈ [symbol] ₘ|i≤t} expresses a general relation between alphabet [symbol] ₘ and alphabets [symbol] ₜ for t≤m.

An example application of an alphabet is in the context of amplitude-shift keying (ASK) constellations. One example includes the symbol (i.e., amplitude) alphabet [symbol] ₘ={1, 3, . . . , 2^{M}−1} so that m=2^{M-1} and {−1, 1}× [symbol] ₘ corresponds to a 2^{M}−ary ASK alphabet (this means that m depends on a modulation order). For instance, for 8-ASK, M=3 and the alphabets [symbol] ₄={1, 3, 5, 7}, [symbol] ₃={1, 3,5}, [symbol] ₂={1, 3} and [symbol] ₁={1}.

A sequence over [symbol] ₘ and having length n is an ordered n-tuple, each element of which takes values in [symbol] ₘ. Disclosure herein may refer to “sequences over [symbol] ₘ and having length n”. By “over [symbol] ₘ” it is meant each element (i.e., symbol) of an involved sequence belongs to the alphabet [symbol] ₘ. In one example sequence, m=2 and n =4, and the symbol sequences of length 4 over [symbol] ₂={1, 3}. In some example wireless applications, m may be relatively small while n may be relatively large.

A composition k of length m and over {0, 1, . . . , n} is an ordered m-tuple k=(k₁, k₂, . . . , kₘ), all elements of which are nonnegative and sum up to n. Given a composition k, kᵢ(k) is the element of k along coordinate i. In other words, kᵢ(k) is the i-th element of k. Given a composition k, examples described herein may denote by n(k) the sum of all elements of k. Given a sequence s of length n over [symbol] ₘ, the composition of s is an ordered m-tuple, k(s)=(k₁(s), k₂(s), . . . , kₘ(s)), where for each i, kᵢ(s) is the number of occurrences of aᵢ∈ [symbol] ₘ in the sequence s. An illustrative example of a sequence includes s=(1, 1, 3, 1), and the prefix s₁²=(1, 1). The composition of sequence s=(1, 1, 3, 1) is k(s) =(3, 1). The element 3 indicates three occurrences of the symbol amplitude 1 in the sequence. The element 1 indicates one occurrence of the symbol amplitude 3 in the sequence. The number of sequences having composition (3, 1) is given by the multinomial coefficient:

$$( ( 3 , 1 ) ) = ( \begin{matrix}n ( ( 3 , 1 ) ) \\ ( 3 , 1 )\end{matrix} ) = \frac{4 !}{3 ! 1 !} = 4. \qquad ( 1 )$$

The sequences over [symbol] ₂ and having composition (3, 1) are (1, 1, 1, 3), (1, 1, 3, 1), (1, 3, 1, 1) and (3, 1, 1, 1). Of course, these examples of an alphabet, sequence, and a composition are for illustration, and it is understood that the scope of embodiments is not limited to any size of alphabet or size of sequence.

Energy of a symbol is another concept within the embodiments described herein. For instance, each different symbol may correspond to a different energy. Given an alphabet [symbol] ₘ of size m, examples denote by E(aᵢ) the energy of symbol aᵢ for each i. In this example, symbol energies are distinct and assumed for any i∈{1, 2, . . . , m−1} that the following relation holds true: 0≤E(aᵢ)<E(aᵢ+1).

One example of symbol energy includes ASK constellations. In such cases, examples may take [symbol] ₘ={1, 3, . . . , 2^{M}−1} so that m=2^{M-1} and {−1, 1}× [symbol] ₘ corresponds to a 2^{M}-ary ASK alphabet so that m depends on a modulation order. In such an example, aᵢ=2i−1 so that a₁=1, a₂=3, . . . , aₘ=2^{M}−1. There is a squared relationship between a symbol and its corresponding energy, as in Examples 1,2 below:
Example 1: for each i, the energy E(aᵢ) of symbol aᵢ satisfies:

$$E ( {a}_{i} ) = {( 2 i - 1 )}^{2} . \qquad ( 2 )$$

Example 2: for each i, the energy E(aᵢ) of symbol aᵢ satisfies:

$$E ( {a}_{i} ) = \frac{i ( i - 1 )}{2} . \qquad ( 3 )$$

There is relation between E(aᵢ) in Example 1 and E(aᵢ) in Example 2. Specifically, if 8i(i−1)/2 +1=(2i−1)², then E(aᵢ) in Example 2 only involves a rescaling of E(aᵢ) in Example 1. Put another way, 8 times E(aᵢ) in Example 2 plus 1 is equal to E(aᵢ) in Example 1.

As noted above, a given symbol corresponds to an energy. Therefore, a sequence of symbols also corresponds to an energy. Given an alphabet [symbol] ₘ of size m, there is a sequence, s=(s₁, s₂, . . . , sₙ), each element of which takes values in [symbol] ₘ. The energy of the sequence s, denoted by E(s), may be defined as the accumulation, i.e., summation, of all symbol energies of symbols belong to the sequence s. For example, the energy E(s) of the sequence s may be determined in accordance with the following Equation (4):

$$E ( s ) = {\sum }_{i = 1}^{n} E ( {s}_{l} ) . \qquad ( 4 )$$

Examples may denote by s₁^{t} the prefix (s₁, s₂, . . . , sₜ) of s so that the sequence s is also denoted by s₁ⁿ. The energy of the prefix s₁^{t} is E(s₁^{t})=Σₜ₌₁^{t}E(sᵢ).

The examples herein denote a cardinality of all sequences having an energy E and a length n as (n, E). E and n are nonnegative integers. The total number of sequences over [symbol] ₘ having length n and energy E is denoted by N^{[m]}(n, E). When the underlying size m is clear from the context, N(n, E) can be used as a proxy.

The examples herein denote a cardinality of all sequences having an energy smaller than or equal to E and a length n as N_{c}(n, E). As noted above, [symbol] ₘ={a₁, a₂, . . . , aₘ} is a finite symbol alphabet of size m, and symbol aᵢ has energy E(aᵢ). The number N_{c}^{[m]}(n, E) is a quantity of symbol sequences over [symbol] ₘ and each sequence having length n and energy at most equal to E. When the underlying size m is clear from the context, N_{c}(n, E) can be used as a proxy.

The number N_{c}(n, E) is a cumulative sequence quantity that can be calculated using recursion. For example, for each n≥1, N_{c}(n, E) satisfies the recursion of Equation (5). The recursion of Equation (5) has an initialization N_{c}(0, E)= [symbol] _{[0,∞)}(E), where [symbol] denotes the indicator function of the set [0, ∞):

$${N}_{c} ( n , E ) = {\sum }_{i = 1}^{m} {N}_{c} ( n - 1 , E - E ( {a}_{i} ) ) . \qquad ( 5 )$$

The examples below use N(n, E) and N_{c}(n, E) (as well as other concepts) to perform encoding. The examples below may refer to N(n, E) as a sequence quantity and may refer to N_{c}(n, E) as a cumulative sequence quantity.

### The Three-Phase AC Encoding Method

In a scenario in which [symbol] (m, n, Ē) is the set of all symbol sequences of length n and over [symbol] ₘ, each sequence has energy at most equal to Ē. In other words, for any s₁ⁿ∈ [symbol] (m, n, Ē), the following is true: E(s₁ⁿ)≤Ē. The cardinality of the set [symbol] (m, n, Ē), i.e., the number of sequences in [symbol] (m, n, Ē), is given by

$$\vert ( m , n , \overline{E} ) \vert = {N}_{c}^{[ m ]} ( n , \overline{E} ) . \qquad ( 6 )$$

When the underlying size m is clear from the context, N_{c}(n, Ē) can be written as a proxy for N_{c}^{[m]}(n, Ē).

The maximum energy Ē depends on [symbol] ₘ and n. For example, if the minimum symbol energy and the maximum symbol energy are respectively E(a₁) and E(aₘ), then the minimum energy and the maximum energy of a length-n symbol sequence over [symbol] ₘ are respectively equal to nE(a₁) and nE(aₘ), which respectively gives the smallest and the largest meaningful Ē. A particular form of Ēis αn, where α is between E(a₁) and E(aₘ) and n is the sequence length.

In one example, α can be taken as the average symbol energy, i.e., α=Σᵢ₌₁^{m}E(aᵢ)/m and α can be taken as a function of e^{-v}, where v is the parameter of a Maxwell-Boltzmann distribution. The three-phase AC encoding method does not rely on any specific choice of Ē.

Some methods described herein include efficient ways to encode (e.g., map) length-k bit sequences into length-n sequences in [symbol] (m, n, Ē) and to guarantee unique decodability.

The input to a given operation of the three-phase AC encoding method is k information bits. The value of k may be determined so that k is the largest integer such that the following is true:

$${2}^{- k} \geq \frac{1}{{N}_{c}^{[ m ]} ( n , \overline{E} )} . \qquad ( 7 )$$

A k-bit sequence (u₁, u₂, . . . , uₖ) of information bits may be interpreted as the dyadic number x∈[0, 1) with the binary expansion 0. u₁u₂ . . . uₖ. The dyadic number may be calculated using a function, such as:

$$x = {\sum }_{i = 1}^{k} {u}_{i} {2}^{- i} . \qquad ( 8 )$$

The dyadic number x, alphabet [symbol] ₘ, sequence length n and maximum energy Ē are available for the three-phase AC encoding method described herein.

The output of a given operation of the three-phase AC encoding method is a length-n sequence of amplitude symbols. The operation of the three-phase AC encoding method maps the sequence (u₁, u₂, . . . , uₖ) to a length-n symbol sequence s=(s₁, s₂, . . . , sₙ) in [symbol] (m, n, Ē). The choice of k guarantees that the mapping is injective.

Each of the three phases may be performed by a wireless communication device, such as those discussed above with respect to FIGS. 1-5. The first phase (or Phase 1) of encoding determines the energy E of the output sequence; i.e., the energy of the output sequence will be E. Phase 1 may include accessing a plurality of N_{c} cumulative sequence quantities and computing ratios based on these N_{c} cumulative sequence quantities such that each such ratio is proportional to an N_{c} cumulative sequence quantity. Each of the plurality of cumulative sequence quantities may be accessed in one of the following ways. In a first example, they may be computed exactly and directly, e.g., using the recursive definition. In a second example, they may be accessed in a look-up table storing such values. In a third example, they may be approximated by an approximation method. The determination of the energy is based on the ratios and the input k-bit sequence (u₁, u₂, . . . , uₖ) via x. Phase 1 may also include a scaling operation related to x.

In the second phase (or Phase 2), and based on E, the wireless communication device determines the composition k*=(k*₁, . . . , k*ₘ) of the output sequence; this is done in m−2 iterations. In each iteration, the wireless communication device determines k* along a coordinate; i.e., a single element of k* is determined in each iteration. The second phase may also include accessing (e.g., computing or approximating or table-looking-up) a plurality of N sequence quantities and binomial coefficients.

Further actions in the second phase may include computing ratios based on these N sequence quantities and binomial coefficients such that each such ratio is proportional to the product of an N sequence quantity and a binomial coefficient. The determination of each element of k* is based on the ratios and the (scaled) input x. Once an element is determined in an iteration, the wireless communication device may perform a scaling operation related to x and update of the residual length and the residual energy. In some examples, the decrementing of residual length is equal to the determined element of k* in a given iteration. The decrement of residual energy may be equal to the product of the determined element of k* and the corresponding symbol energy.

Based on k* and output from Phase 2, the third phase (or Phase 3) determines the symbols of the output sequence sequentially in n iterations. In other words, Phase 2 may include determining the elements of the composition of the output sequence. However, there may be multiple output sequence candidates having the same composition. Phase 3 may determine the output symbols and their order, thereby determining the output symbol itself.

FIG. 6 is an illustration of a first phase of a three-phase AC encoding method, according to one implementation. FIG. 6 illustrates a first interval 610, denoted by [0, 1) and also referred to as a unit interval. The scope of implementations is not limited to any interval, as any appropriate interval may be used. However, the examples presented here may use [0, 1) for ease of explanation.

Before the first phase begins, it is assumed that the device performing the encoding has received a plurality (k) of information bits, wherein k is an integer greater than 1, such as shown in FIG. 5. During the first phase, the wireless communication device accesses a first plurality of values, each value of the first plurality of values representing a quantity of symbol sequences of a length (n) and having at most a respective energy level. For instance, the first phase may include accessing a plurality of N_{c} cumulative sequence quantities.

The first phase may also include processing the cumulative sequence quantities, including selecting a first energy level based at least in part on the plurality of information bits and the cumulative sequence quantities. As described below, processing the N_{c} cumulative sequence quantities may include calculating ratios, each of those ratios representing a transition probability, and then determining a ratio that corresponds to the value of the dyadic number x. As noted above, the dyadic number may be determined from the plurality of information bits.

The first phase of encoding determines a number E between 0 and Ē. The number E specifies the energy of the output sequence and it is selected according to:

$$x ∈ [ \frac{{N}_{c} ( n , E - 1 )}{{N}_{c} ( n , \overline{E} )} , \frac{{N}_{c} ( n , E )}{{N}_{c} ( n , \overline{E} )} ) . \qquad ( 9 )$$

The determination of E using the above condition can be realized by a bisection method of the interval [0, 1), since N_{c} is increasing in its second argument. The first phase effectively partitions the set [symbol] (m, n, Ē) into subsets, with each subset having all sequences that have equal energy, and each subset corresponding to a subinterval of the interval [0, 1).

The dyadic number x falls within the interval [0, 1) (shown as interval 610) and in fact falls within one of the subintervals within the interval. The wireless communication device selects the interval that includes the value of the dyadic number. In this example, the wireless communication device selects subinterval 601, which corresponds to all sequences in [symbol] (m, n, Ē) that has energy equal to E, and its length is proportional to N_{c}(n, E)−N_{c}(n, E−1)=N(n, E). Phase 2 begins with the energy equal to E.

Then, the dyadic number x is scaled to x′ according to:

$${x}^{′} = \frac{{N}_{c} ( n , \overline{E} ) x - {N}_{c} ( n , E - 1 )}{N ( n , E )} . \qquad ( 10 )$$

FIG. 6 shows the interval [0, 1) divided into six subintervals labeled 1-6, each one of the subintervals 1-6 corresponding to a transition probability defined by one of the ratios. Specifically, each such subinterval corresponds to a distinct set of all symbol sequences of length n and over [symbol] ₘ, each sequence of which has energy equal to a distinct [symbol] , denoted here as {m, n, [symbol] }. The partitioning of the unit interval [0, 1) corresponds to the disjoint union property:

$$\{ m , n , \overline{E} \} = {⋃}_{} {\{ m , n , \}}_{=} . \qquad ( 11 )$$

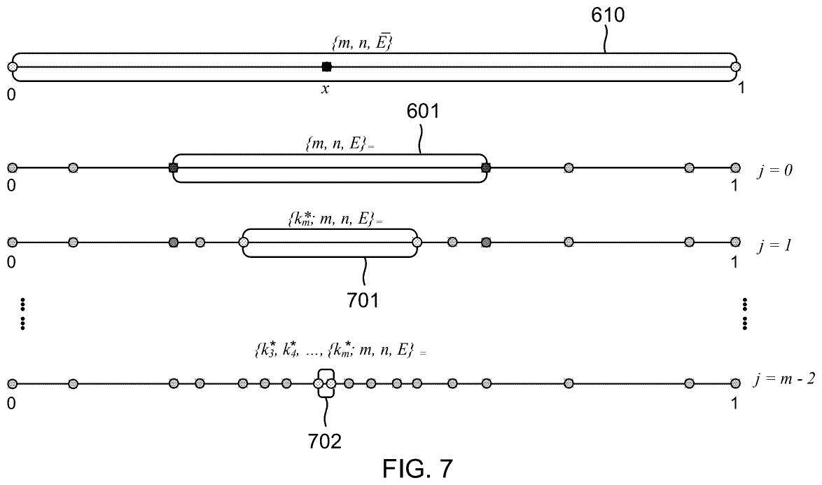

Phase 2 begins with the energy having been selected and the number x having been scaled. FIG. 7 is an illustration of Phases 1 and 2, shown with respect to subintervals, according to one implementation. Phase 2 determines the composition elements k*₁, k*₂, . . . , k*ₘ through multiple iterations, one composition element per iteration, constrained by the energy that was selected in Phase 1. Though the present example determines the elements of the composition k* in the order of k*ₘ, k*ₘ₋₁, . . . , k*₃ , k*₂, k*₁ (e.g., k*ₘ, is determined in the first iteration), the ordering is not a restriction, and any appropriate ordering may be used.

The second phase of encoding initializes j=0, n₀=n, E₀=E and x₀=x′ with E and x′ determined in the first phase of encoding. The second phase of encoding iterates the following until (and including) j=m−3. In other words, the iteration described below is an iteration j, where j starts from 0 and serves as indexing the number of iterations performed so far. There is a sequential manner that is captured by j.

The iteration j includes computing the ratios (transition probabilities) p(·|m−j, nⱼ, Eⱼ) according to:

$$( 12 )$$

$$p ( {k}_{m - j} \vert m - j , {n}_{j} , {E}_{j} ) {=}^{Δ} \frac{( \begin{matrix}{n}_{j} \\ {k}_{m - j}\end{matrix} ) {N}^{[ m - j - 1 ]} ( {n}_{j} - {k}_{m - j} , {E}_{j} - {k}_{m - j} E ( {a}_{m - j} ) )}{{N}^{[ m - j ]} ( {n}_{j} , {E}_{j} )}$$

in which kₘ₋ⱼ is a nonnegative integer within a range specified according to the rounding operation of the following Equation (13):

$$0 \leq {k}_{m - j} \leq ⌊ \frac{{E}_{j}}{E ( {a}_{m - j} )} ⌋ . \qquad ( 13 )$$

The rounding operation is applied to a number and the number is rounded down to the nearest integer. For example, └3.6┘=3. A range refers to a set of integers from 0 to a rounded-down number; i.e., the left-hand side of Equation (13) and the right-hand side of Equation (13). Eⱼ in Equation (13) is the residual energy at the beginning of iteration j (e.g., after performing the first j−1 iterations).

The iteration j includes determining k*ₘ₋ⱼ such that xⱼ belongs to an interval with left-closed and right-open boundaries of the following form:

$${x}_{j} ∈ [ {\sum }_{κ = 0}^{{k}_{m - j}^{*} - 1} p ( κ \vert m - j , {n}_{j} , {E}_{j} ) , {\sum }_{κ = 0}^{{k}_{m - j}^{*}} p ( κ \vert m - j , {n}_{j} , {E}_{j} ) ) . \qquad ( 14 )$$

The iteration j includes updating the value of x by scaling xⱼ to xⱼ₊₁ according to:

$${x}_{j + 1} = \frac{{x}_{j} - {\sum }_{κ = 0}^{{k}_{m - j}^{*} - 1} - p ( κ \vert m - j , {n}_{j} , {E}_{j} )}{p ( {k}_{m - j}^{*} \vert m - j , {n}_{j} , {E}_{j} )} . \qquad ( 15 )$$

The iteration j includes updating the residual length nⱼ₊₁=nⱼ−kₘ₋ⱼ and the residual energy Eⱼ₊₁=Eⱼ−k*ₘ₋ⱼE(aₘ₋ⱼ).

The iteration j includes increasing j by 1, and this completes iteration j.

The above iterations of the second phase sequentially determine k*ₘ, k*ₘ₋₁, . . . , k*₃, which specifies the number of occurrences of the symbols aₘ, aₘ₋₁, . . . , a₃ that will appear in the output sequence s, respectively. The first element k*₁ of k* and the second element k*₂ of k* are subsequently determined by the length and energy conditions. In other words, by the end of the last iteration, nₘ₋₂ is the residual length and Eₘ₋₂ is the residual energy, which means that k*₁+k*₂=nₘ₋₂ and that k*₁E(a₁)+k*₂E(a₂)=Eₘ₋₂. Therefore, the final two composition elements k*₁ and k*₂ may be determined algebraically by solving these two equations. Alternatively, various embodiments may perform m iterations, though that may in some instances be more computationally intensive than performing m−2 iterations and then solving algebraically for the final two composition elements.

The second phase of encoding effectively considers the partitioning of the set {m, n, E}₌ of all sequences in [symbol] (m, n, Ē)≡{m, n, Ē}, such that each sequence in {m, n, E}₌ has energy equal to E, where E is determined in the first phase of encoding.

For 0≤j≤m−3, {kₘ₋ⱼ₊₁, . . . , kₘ; m, n, E} _ is the set of all sequences in {m, n, E}₌ such that the number of occurrences of symbol aᵢ for each such sequence is equal to kᵢ. This holds for all i∈{m−j+1, . . . , m}.

Iteration j corresponds to the set {k*ₘ₋ⱼ₊₁, . . . , k*ₘ; m, n, E}₌. In other words, at the beginning of iteration j, the elements k*ₘ₋ⱼ₊₁, . . . , k*ₘof the composition k* have been determined (which are sequentially done during the first j−1 iterations). Iteration j considers partitioning of {k*ₘ₋ⱼ₊₁, . . . , k*ₘ; m, n, E}₌ into subsets of the form {kₘ₋ⱼ, k*ₘ₋ⱼ₊₁, . . . , k*ₘ; m, n, E}₌.

The ratio of the cardinality of {kₘ₋ⱼ, k*ₘ₋ⱼ₊₁, . . . , k*ₘ; m, n, E}₌ over that of {k*ₘ₋ⱼ₊₁, . . . , k*ₘ; m, n, E}₌ is p(kₘ₋ⱼ|m−j, nⱼ, Eⱼ). That is, the ratio satisfies:

$$\frac{\vert {\{ {k}_{m - j} , {k}_{m - j + 1}^{*} , … , {k}_{m}^{*} ; m , n , E \}}_{=} \vert}{\vert {\{ {k}_{m - j + 1}^{*} , … , {k}_{m}^{*} ; m , n , E \}}_{=} \vert} = \frac{( \begin{matrix}{n}_{j} \\ {k}_{m - j}\end{matrix} ) {N}^{[ m - j - 1 ]} ( {n}_{j} - {k}_{m - j} , {E}_{j} - {k}_{m - j} E ( {a}_{m - j} ) )}{{N}^{[ m - j ]} ( {n}_{j} , {E}_{j} )} . \qquad ( 16 )$$

FIG. 7 illustrates a process of interval refinement in Phase 2 over a series of iterations from j=0 to j=m−2. Phase 1 is also illustrated, as it refines the interval of [0, 1) to the subinterval 601. The first iteration of Phase 2 refines to subinterval 701, and further intervals eventually provide subinterval 702, for a total of m−2 refinements in Phase 2.

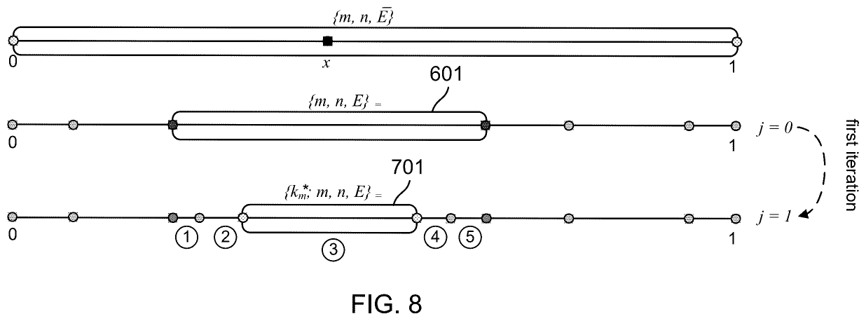

FIG. 8 provides an illustration of the first iteration of Phase 2, as subinterval 601 is refined to subinterval 701, according to one implementation. During the first iteration, the wireless communication device may calculate multiple transition probabilities, wherein each transition probability corresponds to a subinterval, labeled 1-5. Each one of the subintervals 1-5 corresponds to a distinct {kₘ; m, n, E}₌. The partitioning of the interval corresponding to {m, n, E}₌ corresponds to the disjoint union property:

$${\{ m , n , E \}}_{=} = {⋃}_{{k}_{m}} {\{ {k}_{m} ; m , n , E \}}_{=} . \qquad ( 17 )$$

The ratio of the cardinality of {kₘ; m, n, E}₌ over the cardinality of {m, n, E}₌ is referred to as a transition probability. The transition probability has a particular form involving a binomial coefficient and two particular N sequence quantities:

$$p ( {k}_{m} \vert m , n , E ) = \frac{\vert {\{ {k}_{m} ; m , n , E \}}_{=} \vert}{\vert {\{ m , n , E \}}_{=} \vert} = \frac{( \begin{matrix}n \\ {k}_{m}\end{matrix} ) {N}^{[ m - 1 ]} ( n - {k}_{m} , E - {k}_{m} E ( {a}_{m} ) )}{{N}^{[ m ]} ( n , E )} . \qquad ( 18 )$$

When determining the first element of the composition in the first iteration of Phase 2, j is initialized as j=0. The sequence quantities are of the form:

$${N}^{[ m - 1 ]} ( n - {k}_{m} , E - {k}_{m} E ( {a}_{m} ) ) . \qquad ( 19 )$$

In Equation (19), km is the variable. The N sequence quantity in Equation (19) defines a set of all sequences over alphabet [symbol] ₘ₋₁={a₁, a₂, . . . , aₘ₋₁} such that each such sequence in the set has length n−kₘ and energy E−kₘE(aₘ). The alphabet [symbol] ₘ₋₁ that corresponds to the first iteration excludes the symbol aₘ, the number of occurrences of which (kₘ) is under determination during the first iteration.

When determining the first composition element in the first iteration of Phase 2, the transition probabilities are proportional to the cardinality of the set {kₘ; m, n, E}₌, where kₘ is the variable. This set represents the set of all sequences over alphabet [symbol] ₘ, with each such sequence having length n and energy equal to E, while the number of occurrences of symbol aₘ is equal to kₘ.

The cardinality corresponding to a kₘ is computed as follows. An observer may think of n positions in total (like n holes) with a task to fill in symbols from [symbol] ₘ. Among these n positions, kₘ positions are first chosen and made to correspond to aₘ. The number of ways to choose kₘ positions out of n is given by the binomial coefficient

$$( \begin{matrix}n \\ {k}_{m}\end{matrix} ) .$$

This corresponds to the extra condition that each sequence in the set {kₘ; m, n, E}₌ must have kₘ symbol aₘ.

After these kₘ positions have been chosen, it is analogous to these positions being “peeled off”. Hence, the Phase 2 may be termed a “peeling method”. There are n−ₖm positions left, and these correspond to sequences over [symbol] ₘ₋₁={a₁, a₂, . . . , aₘ₋₁} such that each sequence has length n−kₘ and each sequence has energy E−kₘE(aₘ).

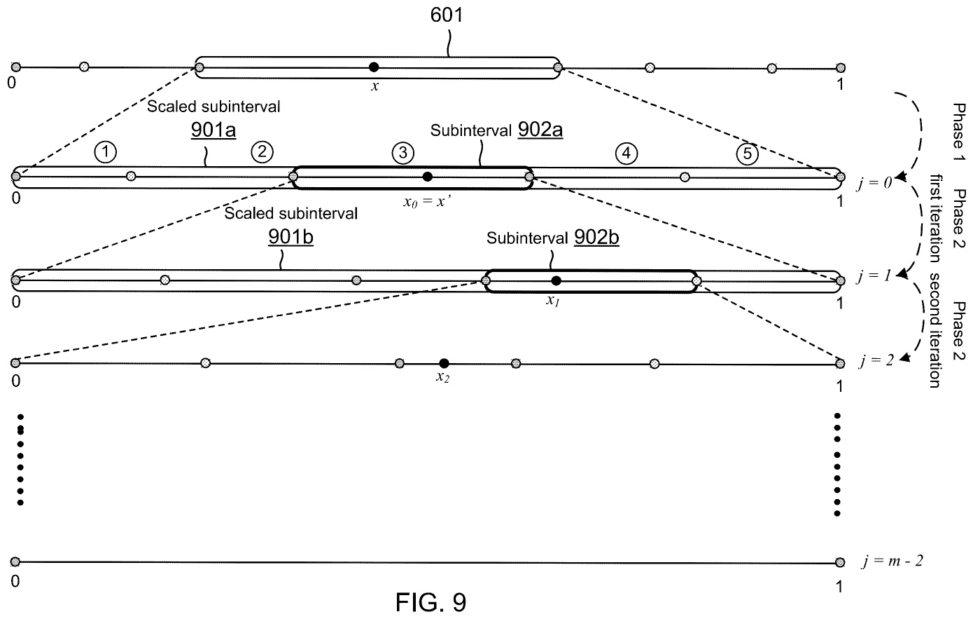

FIG. 9 is an illustration of encoding in Phase 2, according to one implementation. Specifically, FIG. 9 illustrates interval scaling, whereas FIGS. 6-8 illustrate interval refinement. Each of the labelled subintervals 1-5 of FIG. 8 is proportional to a transition probability of the form p(kₘ|m, n, E). Similarly, each of the labelled subintervals 1-5 in FIG. 9 is equal to a transition probability p(kₘ|m, n, E).

FIG. 9 shows a plurality of iterations of Phase 2. For example, in a first iteration (j=0), the wireless communication device may identify a first range of nonnegative integers in accordance with Equation (13). That is, any integer in the first range is between 0 and [E₀/E(aₘ)], where E₀ is equal to E that is determined in the first phase of encoding. The wireless communication device may determine multiple binomial coefficients, e.g.,

$$( \begin{matrix}n \\ {k}_{m}\end{matrix} ) ,$$

and multiple sequence quantities, e.g., N^{[m-1]}(n−kₘ, E−kₘE(aₘ)). In this iteration, kₘ denotes an integer in the first range. Each binomial coefficient corresponds to a respective integer in the first range and each sequence quantity corresponds to a respective integer in the first range as well. The wireless communication device may further compute a first plurality of transition probabilities in accordance with Equation (12), e.g.,

$$p ( {k}_{m} \vert m , n , E ) = \frac{( \begin{matrix}n \\ {k}_{m}\end{matrix} ) {N}^{[ m - 1 ]} ( n - {k}_{m} , E - {k}_{m} E ( {a}_{m} ) )}{{N}^{[ m ]} ( n , E )} . \qquad ( 20 )$$

Each transition probability corresponds to a respective integer in the first range. For example, the transition probability p(kₘ|m, n, E) corresponds to an integer kₘ in the first range. The wireless communication device may partition a scaled subinterval 901a into multiple subintervals based at least in part on the first plurality of transition probabilities. Each subinterval corresponds to a respective transition probability, and the length of each subinterval is equal to a respective transition probability. For example, the subinterval corresponding to p(kₘ|m, n, E) is [Σ_{κ=0}^{k}^{ₘ}⁻¹p(κ|m, n, E), Σ_{κ=0}^{k}ₘp(κ|m, n, E)), and the length of this subinterval is equal to p(kₘ|m,n,E).

The wireless communication device may further identify a subinterval 902a of the scaled subinterval 901a using the number x′ in Equation (10) and the multiple subintervals (labelled 1-5 in FIG. 9), and the identifying is in accordance with Equation (14). That is, the number x′is in the subinterval 902a or, put another way, the number x′ corresponds to a first transition probability that the subinterval 902a corresponds to. The wireless communication device may identify the integer that the first transition probability corresponds to. The identified integer is set to be a first element k*ₘ of the composition k*. The wireless communication device may further apply a scaling operation to the number x′ according to Equation (15), thereby resulting in a second number x₁. Additionally, the wireless communication device may apply a scaling operation on the subinterval 902a, thereby generating a scaled subinterval 901b. The wireless communication device may update the residual length and the residual energy such that n₁=n−k*ₘ and E₁=E−k*ₘE(aₘ). That ends the iteration in which j =0.

In a subsequent iteration (j=1) wherein m>2, the wireless communication device may identify a second range of nonnegative integers in accordance with Equation (13). The second range may include any integer between 0 and └E1/E(aₘ₋₁)┘. The wireless communication device may determine multiple binomial coefficients, e.g.,

$$( \begin{matrix}{n}_{1} \\ {k}_{m - 1}\end{matrix} )$$

and multiple sequence quantities, e.g., N^{[m-2]}(n₁−kₘ₋₁, E₁−kₘ₋₁E(aₘ₋₁)). Here, kₘ₋₁ denotes an integer in the second range. Each binomial coefficient corresponds to a respective integer in the second range and each sequence quantity corresponds to a respective integer in the second range as well. The wireless communication device may further compute a second plurality of transition probabilities in accordance with Equation (12); for example,

$$p ( {k}_{m - 1} \vert m - 1 , {n}_{1} , {E}_{1} ) = \frac{( \begin{matrix}{n}_{1} \\ {k}_{m - 1}\end{matrix} ) {N}^{[ m - 2 ]} ( {n}_{1} - {k}_{m - 1} , {E}_{1} - {k}_{m - 1} E ( {a}_{m - 1} ) )}{{N}^{[ m - 1 ]} ( {n}_{1} , {E}_{1} )} . \qquad ( 21 )$$

Each transition probability corresponds to a respective integer in the second range. For example, the transition probability p(kₘ₋₁|m−1, n₁, E₁) corresponds to an integer kₘ₋₁ in the second range. The wireless communication device may partition the scaled subinterval 901b into multiple subintervals based at least in part on the second plurality of transition probabilities. Each subinterval corresponds to a respective transition probability, and the length of each subinterval is equal to a respective transition probability. For example, the subinterval corresponding to p(kₘ₋₁|m−1, n₁, E₁) is [Σ_{κ=0}^{k}^{_{m−1}}⁻¹p(κ|m−1, n₁, E₁), Σ_{κ=0}^{K}^{_{m−1}}p(κ|m−1, n₁, E₁), and the length of this subinterval is equal to p(kₘ₋₁|m−1, n₁, E₁).

The wireless communication device may further identify a subinterval 902b of the scaled subinterval 901b using the second number x₁ and the multiple subintervals, and the identifying is in accordance with Equation (14). That is, the number x₁ is in the subinterval 902b; or put another way, the number x₁ corresponds to a second transition probability that the subinterval 902b corresponds to. The wireless communication device may identify the integer that the second transition probability corresponds to. That integer is set to be a second element k*ₘ₋₁ of the composition k*. The wireless communication device may further apply a scaling operation to the number x₁ in accordance with Equation (15). Additionally, the wireless communication device may apply a scaling operation on the subinterval 902b. The wireless communication device may update the residual length and the residual energy such that n₂=n₁−k*ₘ₋₁ and E₂=E₁−kₘ₋₁E(aₘ₋₁).

That ends the iteration in which j=1. The iterations continue through j=m−2, at which point algebraic means may be used to determine the final two composition elements.

The value N_{c}^{[m]}(n, [symbol] ) for general [symbol] used in the first phase of encoding can be accessed by the wireless communication device. In this example, [symbol] denotes a nonnegative integer smaller than or equal to Ē, and m, n and Ē correspond to [symbol] (m, n, Ē), which is the set of all sequences generated using the alphabet [symbol] ₘ, each sequence having a length n, and having an energy that may be less than or equal to (e.g., at most) Ē. The value N^{[m]}(n, [symbol] ) may be accessed by one or more ways. In a first example, the value may be computed exactly and directly, e.g., using the recursive definition. In a second example, the value may be accessed in a look-up table storing such values. In a third example, the value may be approximated by an approximation method, in which case the approximate value may be denoted by [symbol] (n, [symbol] ). In the third case, the first phase of encoding replaces the exact values with approximate values, and selects the number E according to:

$$x ∈ [ \frac{( n , E - 1 )}{( n , \overline{E} )} , \frac{( n , E )}{( n , \overline{E} )} ) . \qquad ( 22 )$$

Accessing the N sequence quantities in Phase 2 of encoding may be performed similarly. The value N^{[m]}(n, [symbol] ) for general m, n and [symbol] used in the second phase of encoding can be accessed by the wireless communication device. In this example, m is an integer such that 1≤m≤m; n is a non-negative integer smaller than or equal to n; [symbol] is a non-negative integer smaller than or equal to Ē. Equation (12) (and Equation (23)) show that Phase 2 of encoding computes or approximates transition probabilities, where \hat{N}^{[m]}(n, [symbol] ) is used for a multiple of m, n, [symbol] values. In another words, m, n, [symbol] may be viewed as 3 variables of N. The value N^{[m]}(n, [symbol] ) may be accessed by one or more ways. In a first example, the value may be computed exactly and directly, e.g., using the recursive definition. In a second example, the value may be accessed in a look-up table storing such values. In a third example, the value may be approximated by an approximation method, in which case the approximate value is denoted by \hat{N}^{[m]}(n, [symbol] ). In the third case, the second phase computes the transition probabilities using the approximate values. For example, the transition probability corresponding to an integer kₘ₋ⱼ may be denoted by \hat{p}(kₘ₋ⱼ|m−j, nⱼ, Eⱼ) and may be computed in accordance with the following Equation (23):

$$( 23 )$$

$$\hat{p} ( {k}_{m - j} \vert m - j , {n}_{j} , {E}_{j} ) {=}^{Δ} \frac{( \begin{matrix}{n}_{j} \\ {k}_{m - j}\end{matrix} ) {\hat{N}}^{[ m - j - 1 ]} ( {n}_{j} - {k}_{m - j} , {E}_{j} - {k}_{m - j} E ( {a}_{m - j} ) )}{{\sum }_{κ ∈ [ {\underline{k}}_{m - j} , {\overline{k}}_{m - j} ]} ( \begin{matrix}{n}_{j} \\ κ\end{matrix} ) {\hat{N}}^{[ m - j - 1 ]} ( {n}_{j} - κ , {E}_{j} - κ E ( {a}_{m - j} ) )} .$$

In Equation (23), kₘ₋ⱼ and k̅ₘ₋ⱼ are integers depending on nⱼ and Eⱼ, which are used to specify the range of kₘ₋ⱼ.

At the end of Phase 2, there is a known energy E, a known length n, and a known composition k*=(k*₁, . . . , k*ₘ). Phase 3 works within those constraints to determine an order of the amplitude symbols within the output sequence.

Phase 3 includes n iterations to determine n amplitude symbols, one amplitude symbol per iteration, of the output sequence. Phase 3 uses transition probabilities p and a number z at each iteration, as shown below.

The third phase of encoding initializes t=0, k₀=(0, 0, . . . , 0)∈ [symbol] ^{m} and z₀=xₘ₋₂. The third phase of encoding iterates the following until (and including) t=n−1.

For each possible i∈{1, 2, . . . , m}, an iteration t computes the transition probability p(kₜ→Kₜ+eᵢ) in accordance with the following. If kᵢ(k*)<kᵢ(kₜ), then the iteration t determines the transition probability p(kₜ→kₜ+eᵢ) to be equal to 0. If kᵢ(k*)≥ kᵢ(kₜ), then the iteration t determines the transition probability p(kₜ→kₜ+eᵢ) in accordance with:

$$p ( {k}_{t} \to {k}_{t} + {e}_{i} ) Δ = \frac{{k}_{i} ( {k}^{*} ) - {k}_{i} ( {k}_{t} )}{n - t} . \qquad ( 24 )$$

In Equation (24) and in examples described herein, eᵢ denotes the m-tuple in [symbol] ^{m} such that the i-th element of eᵢ is equal to 1 and the j-th element of eᵢ is equal to 0 for any j≠i.

The iteration t determines j≡jₜ₊₁∈{1,2, . . . , m} such that:

$${z}_{t} ∈ [ {\sum }_{i = 1}^{j - 1} p ( {k}_{t} \to {k}_{t} + {e}_{i} ) , {\sum }_{i = 1}^{j} p ( {k}_{t} \to {k}_{t} + {e}_{i} ) ) . \qquad ( 25 )$$

The iteration t then outputs symbol sₜ₊₁ by setting sₜ₊₁=aⱼ and scales zₜ to zₜ₊₁ according to:

$${z}_{t + 1} = \frac{{z}_{t} - {\sum }_{i = 1}^{j - 1} p ( {k}_{t} \to {k}_{t} + {e}_{i} )}{p ( {k}_{t} \to {k}_{t} + {e}_{j} )} . \qquad ( 26 )$$

The iteration t then updates the prefix composition kₜ₊₁=kₜ+eⱼ, increases t by 1, and this completes iteration t. Further iterations are performed (if any iterations remain).

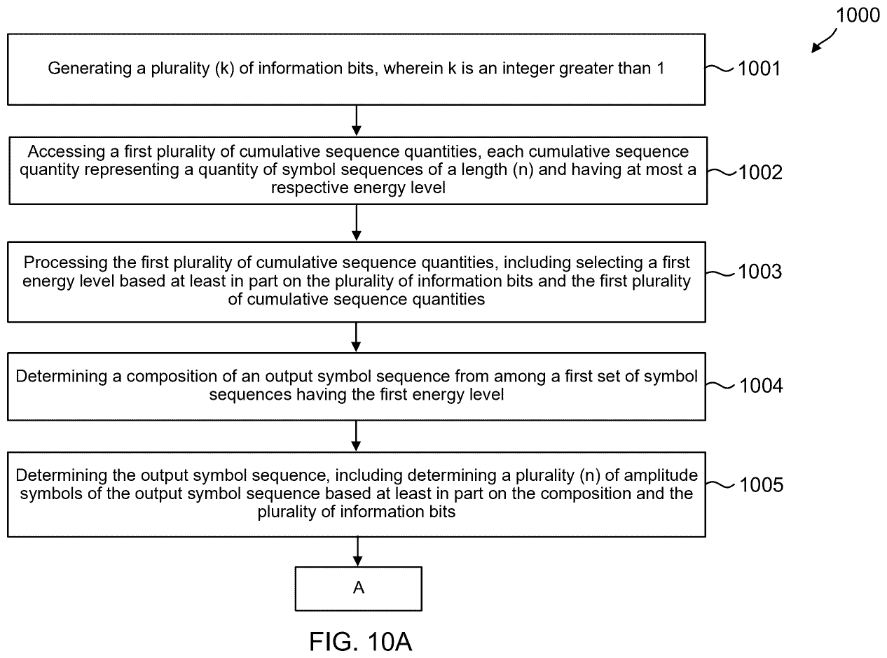

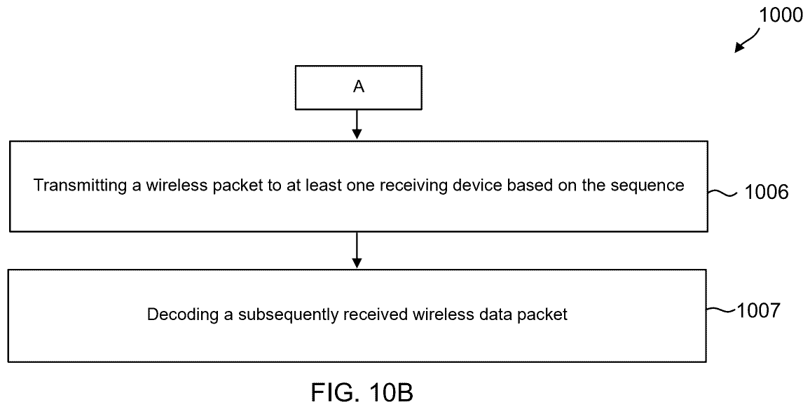

FIGS. 10A and 10B present an illustration of example method 1000 for three-phase AC encoding, according to one implementation. Method 1000 may be performed, e.g., by a wireless communication device such as those discussed above with respect to FIGS. 1-5.

At action 1001, the wireless communication device generates a plurality (k) of information bits. In this example, k is an integer greater than 1.

Actions 1002-1003 correspond to Phase 1 of the encoding method. Specifically, at action 1002, the wireless communication device accesses a first plurality of values. Each of the plurality of values represents a quantity of symbol sequences of length (n) and having at most a respective energy level. For example, the wireless communication device may calculate a plurality of N_{c} cumulative sequence quantities.

At action 1003, the wireless communication device processes the cumulative sequence quantities. In one example, the wireless communication device may select a first energy level based at least in part on the plurality of information bits and the first plurality of cumulative sequence quantities (N_{c}). Selecting the first energy level may include generating a first number (x) by performing a first function, computing a set of ratios that are associated with respective values of the first plurality of cumulative sequence quantities, and using the first number to select a first one of the ratios that corresponds to the first energy level. The ratios may be computed based on the cumulative sequence quantities N_{c} such that each ratio is proportional to an N_{c} cumulative sequence quantity.

Action 1003 may also include a scaling operation for the first number.

Action 1004 corresponds to Phase 2 of the encoding method. Action 1004 includes determining a composition of an output symbol sequence from among a first set of symbol sequences (e.g., {m, n, E}₌) having the first energy level, including performing a plurality of iterations to identify a plurality of elements of the composition. A quantity (m) of the plurality of iterations is related to a size of a symbol alphabet ( [symbol] ₘ) to which the first set of symbol sequences belongs. For instance, some embodiments may include a number of iterations equal to m minus 2 and then determining the final two elements algebraically. As explained above a composition k of length m and over {0, 1, . . . , n} is an ordered m-tuple k=(k₁, k₂, . . . , kₘ), all elements of which are nonnegative and sum up to n.

A first iteration of action 1004 may include calculating a first number (x′) based at least in part on the plurality of information bits. The first iteration may also include accessing a plurality of sequence quantities (e.g., a plurality of N sequence quantities), each one of the sequence quantities defining a set of all sequences having a length n minus a variable kₘ, an energy having been reduced by an amount proportional to the variable kₘ, and a symbol alphabet excluding a first amplitude symbol, using kₘ over a range of possible candidates for a first element. The first iteration may also include accessing a plurality of binomial coefficients and computing a plurality of transition probabilities based on the sequence quantities N and the binomial coefficients. The transition probabilities may include ratios based on these N sequence quantities and binomial coefficients such that each such ratio is proportional to the product of an N sequence quantity and a binomial coefficient; the determination of each element of k* is based on the ratios and the first number x′. The element determined in the first iteration may be denoted as km*.

In this example, the first iteration begins with a first subinterval of a first interval, the first interval corresponding to the set {m, n, Ē}. The first iteration defines a second subinterval from the first subinterval. The first subinterval corresponds to the first set of symbol sequences, and the second subinterval corresponds to a second set of symbol sequences {kₘ; m, n, E}₌. The first subinterval has a length that is proportional to a first transition probability, and the second set of symbol sequences corresponds to a reduction of the first set of symbol sequences to exclude ones of the symbol sequences that do not conform to a first element of the composition. The next iteration may then repeat by scaling the first number again, generating a residual energy value and a residual length value, and calculating the transition probabilities constrained by the residual energy value and the residual length value. For instance, in a second iteration, kₘ₋₁ may denote the variable used to access the sequence quantities, and kₘ₋₁* may denote the determined element.

At action 1005, the wireless communication device determines the output symbol sequence, and this corresponds to Phase 3 of the encoding method. Action 1005 may include determining a plurality (n) of amplitude symbols of the output symbol sequence based at least in part on the composition and the plurality of information bits. For instance, the wireless communication device may perform n iterations, one iteration for each amplitude symbol of the output symbol sequence. For instance, in the examples above, the wireless communication device performs n iterations, using a number z, and updating a prefix composition with each iteration.

At action 1006, the wireless communication device transmits a wireless packet to at least one receiving device based on the output symbol sequence. For instance, the output symbol sequence may be enhanced by forward error correction, converted into constellation points, and transmitted wirelessly to the receiving device.

At action 1007, the wireless communication device may decode a subsequently received wireless data packet. An example of decoding is described below.

### The Three-Phase AC Decoding Method

Various implementations also include decoding received amplitude symbols, performed, e.g., by a wireless communication device that receives a data packet encoded according to the three-phase AC encoding method. For instance, the input of decoding may include a length-n symbol sequence s=(s₁, s₂, . . . , sₙ) encoded by the three-phase AC encoding method is received and available for decoding. The sequence s has length n and energy at most Ē, and each element of s is from the alphabet [symbol] ₘ. The alphabet [symbol] ₘ and the maximum energy Ē are available for decoding.

The three-phase AC decoding maps the sequence s to a length-k bit sequence ( [symbol] , [symbol] , . . . , [symbol] ) as an estimate of the information bit sequence (u₁, u₂, . . . , uₖ). The choice of k satisfies the same condition as described above with respect to encoding and, thus, guarantees unique decodability. As with the encoding, decoding may also be performed in three phases.

The first phase of decoding forms an initial estimate (x₀ and x̅₀) of the information bits based on the energy of the received sequence s. The wireless communication device computes the energy E of the received sequence s=(s₁, s₂, . . . , Sₙ). The wireless communication device also accesses (e.g., computing or approximating or table-looking-up) a plurality of N_{c} cumulative sequence quantities. The wireless communication device also computes ratios based on these N_{c} cumulative sequence quantities such that each such ratio is proportional to an N_{c} cumulative sequence quantity.

For instance, based on the sequence s=(s₁, s₂, . . . , sₙ), the first phase of decoding obtains the energy E of the sequence s according to

$$E = E ( s ) = {\sum }_{l = 1}^{n} E ( {s}_{l} ) . \qquad ( 27 )$$

Then, the device computes x₀ and x̅₀ according to:

$${\underline{x}}_{0} = \frac{{N}_{c} ( n , E - 1 )}{{N}_{c} ( n , \overline{E} )} \qquad ( 28 )$$

$${\overline{x}}_{0} = \frac{{N}_{c} ( n , E )}{{N}_{c} ( n , \overline{E} )} . \qquad ( 29 )$$

Once the device has computed x₀ and x̅₀, then the decoding is initialized for the second phase of decoding (or decoding phase 2). The energy E, x₀ and x̅₀ are subsequently used in the second phase of decoding. More precisely, the second phase of decoding initializes j=0, n₀=n, E₀=E, and uses x₀ and x̅₀ as the initialization for the iterations.

The second phase of decoding (or decoding phase 2) forms refined estimates (xⱼ and x̅ⱼ) of the information bits based on the composition k* of s. The second phase of decoding may include computing the composition k* of the received sequence s=(s₁, s₂, . . . , sₙ). The second phase of decoding is done sequentially in m−2 iterations. The second phase of decoding is may further include accessing (e.g., computing or approximating or table-looking-up) a plurality of N sequence quantities and binomial coefficients. The second phase of decoding is may further include computing ratios based on these N sequence quantities and binomial coefficients such that each such ratio is proportional to the product of an N sequence quantity and a binomial coefficient. The second phase of decoding is may further include obtaining new refined estimates (xⱼ₊₁ and x̅ⱼ₊₁) from previous refined estimates (xⱼ and x̅ⱼ). The second phase of decoding may further include an update of the residual length and the residual energy.

The second phase of decoding iterates the following until (and including) j=m−3.

Based on the sequence s=(s₁, s₂, . . . , sₙ) and the alphabet [symbol] ₘ, an iteration j of the second phase of decoding first determines:

$${k}_{m - j}^{*} = \vert \{ i \vert 1 \leq i \leq n , {s}_{i} = {a}_{m - j} \} \vert . \qquad ( 30 )$$

The iteration j then computes the ratios (transition probabilities) p (·|m−j, nⱼ, Eⱼ) according to:

$$( 31 )$$

$$p ( {k}_{m - j} \vert m - j , {n}_{j} , {E}_{j} ) = \frac{( \begin{matrix}{n}_{j} \\ {k}_{m - j}\end{matrix} ) {N}^{[ m - j - 1 ]} ( {n}_{j} - {k}_{m - j} , {E}_{j} - {k}_{m - j} E ( {a}_{m - j} ) )}{{N}^{[ m - j ]} ( {n}_{j} , {E}_{j} )} , where 0 \leq {k}_{m - j} \leq {k}_{m - j}^{*} .$$

The iteration j then updates xⱼ and x̅ⱼ to xⱼ₊₁ and x̅ⱼ₊₁ respectively according to:

$${\underline{x}}_{j + 1} = {\underline{x}}_{j} + ( {\overline{x}}_{j} - {\underline{x}}_{j} ) {\sum }_{κ = 0}^{{k}_{m - j}^{*} - 1} p ( κ \vert m - j , {n}_{j} , {E}_{j} ) \\ and \qquad ( 32 )$$

$${\overline{x}}_{j + 1} = {\underline{x}}_{j} + ( {\overline{x}}_{j} - {\underline{x}}_{j} ) {\sum }_{κ = 0}^{{k}_{m - j}^{*}} p ( κ \vert m - j , {n}_{j} , {E}_{j} ) . \qquad ( 33 )$$

The iteration j updates the residual length nⱼ₊₁=nⱼ−kₘ₋ⱼ and the residual energy Eⱼ₊₁=Eⱼ−kₘ₋ⱼE(aₘ₋ⱼ) and increases j by 1, and this completes iteration j. Further iterations are performed (if any iterations remain). The output of the second phase of decoding is the composition k*=(k*₁, . . . , k*ₘ).

The third phase of decoding (or decoding phase 3) provides a final estimate ( [symbol] , [symbol] , . . . , [symbol] ) of the information bits. This is done sequentially in n iterations and is based on the composition k* and the refined estimates xₘ₋₂ and x̅ₘ₋₂ from decoding phase 2.

The third phase of decoding then initializes t=0, z₀=xₘ₋₂ and z̅₀=x̅ₘ₋₂ and uses the composition k*=(k*₁, . . . , k*ₘ). The third phase of decoding iterates the following until (and including) t=n−1.

For each possible i∈{1, 2, . . . , m}, an iteration t computes the transition probability p(kₜ→kₜ+eᵢ) in accordance with the following. If kᵢ(k*)<kᵢ(kₜ), then the iteration t determines the transition probability p(kₜ→kₜ+eᵢ) to be equal to 0. If kᵢ(k*)≥kᵢ(kₜ), then the iteration t determines the transition probability p(kₜ→kₜ+eᵢ) in accordance with:

$$p ( {k}_{t} \to {k}_{t} + {e}_{i} ) {=}^{Δ} \frac{{k}_{i} ( {k}^{*} ) - {k}_{i} ( {k}_{t} )}{n - t} . \qquad ( 34 )$$

Then the iteration t determines j≡jₜ₊₁∈{1,2, . . . , m} such that aⱼ=sₜ₊₁; i.e., sₜ₊₁ in the received sequence s is aⱼ. The iteration t then updates the numbers zⱼ and z̅ⱼ to zⱼ₊₁ and z̅ⱼ₊₁ respectively according to:

$${\underline{z}}_{t + 1} = {\underline{z}}_{t} + ( {\overline{z}}_{t} - {\underline{z}}_{t} ) {\sum }_{i = 1}^{j - 1} p ( {k}_{t} \to {k}_{t} + {e}_{i} ) \\ and \qquad ( 35 )$$

$${\overline{z}}_{t + 1} = {\underline{z}}_{t} + ( {\overline{z}}_{t} - {\underline{z}}_{t} ) {\sum }_{i = 1}^{j} p ( {k}_{t} \to {k}_{t} + {e}_{i} ) \qquad ( 36 )$$

The iteration t updates the prefix composition kₜ₊₁=kₜ+eⱼ, increases t by 1, and this completes iteration t.

The output bit sequence ( [symbol] , [symbol] , . . . , [symbol] ) is determined as follows. If z̅ₙ is not a dyadic number of the form j2^{-k}, the decoding takes the first k bits of the binary expansion of z̅ₙ as the decoded output. Otherwise, the decoding takes the first k bits of the binary expansion of zₙ as the decoded output.

### Variation on the Three-Phase AC Encoding and Decoding Methods

In the examples above, the three-phase AC encoding method began by determining an energy E, and the three-phase AC decoding method began with an assumption that the encoding used E. However, another variation may include Phase 1 of encoding to map bit sequences to symbol sequences such that the energy of each symbol sequence is in a subset of {0, 1, 2, . . . , Ē}. More precisely, a set ε is introduced where ε={ε₁, ε₂, . . . , !_{K}}, and where εⱼ∈{0, 1, 2, . . . , Ē} for each j and ε₁<ε₂<· · · <ε_{K}. [symbol] (m, n, ε) denotes the set of all sequences over [symbol] ₘ and having length n, each sequence of which has energy belonging to ε. In this variation example, [symbol] (m, n, ε) is a subset of [symbol] (m, n, Ē). The variation allows for mapping bit sequences to symbol sequences having identical energy.

During Phase 1 of encoding for this variation, | [symbol] (m, n, ε)| denotes the cardinality of [symbol] (m, n, ε), and the input bit length k is determined as the largest integer such that the following is true:

$${2}^{- k} \geq \frac{1}{\vert 𝒮 ( m , n , ℰ ) \vert} . \qquad ( 37 )$$

The first phase of encoding selects E=εⱼ such that:

$$x ∈ [ \frac{{\sum }_{i = 1}^{j - 1} N ( n , {ℰ}_{i} )}{{\sum }_{i = 1}^{K} N ( n , {ℰ}_{i} )} , \frac{{\sum }_{i = 1}^{j} N ( n , {ℰ}_{i} )}{{\sum }_{i = 1}^{K} N ( n , {ℰ}_{i} )} ) . \qquad ( 38 )$$

Then, x is scaled to x′ according to

$${x}^{′} = \frac{x {\sum }_{i = 1}^{K} N ( n , {ℰ}_{i} ) - {\sum }_{i = 1}^{j - 1} N ( n , {ℰ}_{i} )}{N ( n , {ℰ}_{j} )} . \qquad ( 39 )$$

This ends the first phase of encoding in this variation, and the second phase and the third phase of encoding are performed similarly to the three-phase AC encoding method described above.

For decoding in the variation, the first phase of decoding receives a sequence s and obtains the energy E of the sequence s according to E=E(s)=Σₗ₌₁ⁿE(sₗ). Then, the decoding selects the index j such that E=εⱼ, where εⱼ ∈ε. Then, the decoding computes x₀ and x̅₀ according to:

$${\underline{x}}_{0} = \frac{{\sum }_{i = 1}^{j - 1} N ( n , {ℰ}_{i} )}{{\sum }_{i = 1}^{K} N ( n , {ℰ}_{i} )} and \qquad ( 40 )$$

$${\overline{x}}_{0} = \frac{{\sum }_{i = 1}^{j} N ( n , {ℰ}_{i} )}{{\sum }_{i = 1}^{K} N ( n , {ℰ}_{i} )} . \qquad ( 41 )$$

The second phase and the third phase of decoding are performed similarly as decoding described above.

A special case of the variation is when K=1 (i.e., a single energy target), and in this case, ε₁=Ē. In this case, the first phase of encoding and decoding can be omitted. Phase 2 of encoding in this variation (involving m−2 iterations) takes as input t=0, nₜ=n, Eₜ=ε₁ and xₜ=x. Phase 2 of decoding in this variation (involving m−2 iterations) takes as input t=0, nₜ=n, Eₜ=E, x₀=0 and x̅₀=1.

### Clauses

Various implementations may be described by the following numbered clauses:

1. A method for wireless communication by a wireless communication device, the method comprising:
generating a plurality (k) of information bits, wherein k is an integer greater than 1;
performing an encoding operation on the plurality of information bits, the encoding operation including:
accessing a first plurality of cumulative sequence quantities, each cumulative sequence quantity of the first plurality of cumulative sequence quantities representing a quantity of symbol sequences of a length (n) and having at most a respective energy level;
processing the first plurality of cumulative sequence quantities, including selecting a first energy level based at least in part on the plurality of information bits and the first plurality of cumulative sequence quantities;
determining a composition of an output symbol sequence from among a first set of symbol sequences having the first energy level, including performing a plurality of iterations to identify a plurality of elements of the composition, a quantity of the plurality of iterations being related to a size of a symbol alphabet; and
determining the output symbol sequence, including determining a plurality (n) of amplitude symbols of the output symbol sequence based at least in part on the composition and the plurality of information bits, wherein n is an integer greater than 1; and
transmitting a wireless packet to at least one receiving device based on the output symbol sequence.

2. The method of clause 1, wherein each of the amplitude symbols is selected from the symbol alphabet having size m, the symbol alphabet defining a set of different amplitude symbols, wherein m is an integer greater than 1.

3. The method of any of clauses 1-2, wherein selecting the first energy level comprises:
performing a first function on the plurality of information bits, the first function generating a first number;
computing a set of ratios, wherein each of the ratios is associated with a respective one of the first plurality of cumulative sequence quantities; and
determining that the first number corresponds to a first one of the ratios, the first one of the ratios corresponding to the first energy level.

4. The method of clause 3, wherein the first number comprises a dyadic number.

5. The method of any of clauses 1-4, further comprising:
receiving a subsequent wireless packet from a transmitting wireless communication device, the subsequent wireless packet including information having a received symbol sequence of n amplitude symbols and a second energy level and defined by the symbol alphabet; and
decoding the subsequent wireless packet, wherein decoding comprises: computing the second energy level, obtaining a second composition of the received symbol sequence by counting symbol occurrences within the subsequent wireless packet; performing a plurality (n) of decoding iterations, each decoding iteration including computing a plurality of transition probabilities and a decoding interval constrained by a prefix composition, and after n of the decoding iterations generating a binary expansion corresponding to a final decoding interval.

6. The method of any of clauses 1-5, wherein identifying a first element (km*) of the plurality of elements of the composition comprises:
calculating a first number based at least in part on the plurality of information bits;
accessing a plurality of sequence quantities, each one of the sequence quantities defining a set of all sequences having a length n minus km, an energy having been reduced by an amount proportional to km, and a symbol alphabet excluding a first amplitude symbol, and using km as a variable over a range of possible candidates for km *;
accessing a plurality of binomial coefficients;
computing a plurality of transition probabilities based on the sequence quantities and the binomial coefficients; and
determining that a first one of the transition probabilities corresponds to the first number, the first one of the transition probabilities corresponding to the first element of the composition.

7. The method of clause 6, further comprising:
generating a residual energy value in accordance with determining the first element of the composition.

8. The method of clause 6, further comprising:
generating a residual length value in accordance with determining the first element of the composition.

9. The method of clause 6, further comprising:
scaling the first number in accordance with determining the first element of the composition.

10. The method of clause 6, further comprising:
performing a second iteration to determine a second element (kₘ₋₁*) of the plurality of elements of the composition, including:
   generating a residual energy value and a residual length value in accordance with determining the first element of the composition;
   calculating a second number based on the plurality of information bits;
   accessing a second plurality of sequence quantities defining a set of all sequences having a second length of the residual length value minus kₘ₋₁, a second energy equal to the residual energy value minus a second amount proportional to kₘ₋₁, and a second symbol alphabet excluding the first amplitude symbol and a second amplitude symbol, using kₘ₋₁ as a variable over a range of possible candidates for kₘ₋₁*;
   accessing a second plurality of binomial coefficients;
   computing a second plurality of transition probabilities based on the second plurality of sequence quantities and the second plurality of binomial coefficients; and
   determining that a second one of the second plurality of transition probabilities corresponds to the second number, the second one of the transition probabilities corresponding to the second element.

11. The method of any of clauses 1-10, wherein a first iteration of the plurality of iterations begins with a first subinterval of a first interval and defines a second subinterval, the first subinterval corresponding to the first set of symbol sequences, and the second subinterval corresponding to a second set of symbol sequences, the first subinterval having a length that is proportional to a first transition probability, the second set of symbol sequences corresponding to a reduction of the first set of symbol sequences to exclude ones of the symbol sequences that do not conform to a first element of the composition.

12. The method of clause 11, further comprising:
scaling a first number according to the reduction of the first set of symbol sequences, wherein the first number is computed using the plurality of information bits.

13. The method of clause 11, further comprising:
scaling the first subinterval to be a same size as the first interval.

14. The method of any of clauses 1-13, wherein the encoding operation and the transmitting is performed by a user equipment (UE).

15. The method of any of clauses 1-14, wherein the encoding operation and the transmitting is performed by a wireless base station (BS).

16. A wireless communication device comprising:
at least one modem;
at least one processor communicatively coupled with the at least one modem; and
at least one memory communicatively coupled with the at least one processor and storing processor-readable code that, when executed by the at least one processor in conjunction with the at least one modem, is configured to:
   generate a plurality of information bits;
   access a first plurality of cumulative sequence quantities, each cumulative sequence quantity of the first plurality of cumulative sequence quantities representing a quantity of symbol sequences of a length (n) and having at most a respective energy level;
   process the first plurality of cumulative sequence quantities, including selecting a first energy level based at least in part on the plurality of information bits and the first plurality of cumulative sequence quantities;
   determine a composition of an output symbol sequence from among a first set of symbol sequences having the first energy level, including performing a plurality of iterations to identify a plurality of elements of the composition, a quantity of the plurality of iterations being related to a size of a symbol alphabet; and
   determine the output symbol sequence, including determining a plurality (n) of amplitude symbols of the output symbol sequence based at least in part on the composition and the plurality of information bits; and
   transmit a wireless packet to at least one receiving device based on the output symbol sequence.

17. The wireless communication device of clause 16, wherein the processor-readable code to cause the wireless communication device to select the first energy level comprises processor-readable code to cause the wireless communication device to:

perform a first function on the plurality of information bits, the first function generating a first number;

compute a set of ratios, wherein each of the ratios is associated with a respective cumulative sequence quantity of the first plurality of cumulative sequence quantities; and
determine that the first number corresponds to a first one of the ratios, the first one of the ratios corresponding to the first energy level.

18. The wireless communication device of any of clauses 16-17, wherein the at least one processor in conjunction with the at least one modem, is further configured to:
receive a subsequent wireless packet from a transmitting wireless communication device, the subsequent wireless packet including information having a received symbol sequence and a second energy level and defined by the symbol alphabet; and
decode the subsequent wireless packet, wherein decoding comprises: computing the second energy level, obtaining a second composition of the received symbol sequence by counting symbol occurrences within the subsequent wireless packet; performing a plurality (n) of decoding iterations, each decoding iteration including computing a plurality of transition probabilities and a decoding interval constrained by a prefix composition, and after n of the decoding iterations generating a binary expansion corresponding to a final decoding interval.

19. The wireless communication device of any of clauses 16-18, wherein the at least one processor in conjunction with the at least one modem, is further configured to:
identify a first element (km*) of the plurality of elements of the composition, including calculating a first number based at least in part on the plurality of information bits;
access a plurality of sequence quantities, each one of the sequence quantities defining a set of all sequences having a length n minus km, an energy having been reduced by an amount proportional to km, and a symbol alphabet excluding a first amplitude symbol, and using km as a variable over a range of possible candidates for kₘ*;
access a plurality of binomial coefficients;
compute a plurality of transition probabilities based on the sequence quantities and the binomial coefficients; and
determine that a first one of the transition probabilities corresponds to the first number, the first one of the transition probabilities corresponding to the first element of the composition.

20. The wireless communication device of any of clauses 16-19, wherein a first iteration of the plurality of iterations begins with a first subinterval of a first interval and defines a second subinterval, the first subinterval corresponding to the first set of symbol sequences, and the second subinterval corresponding to a second set of symbol sequences, the first subinterval having a length that is proportional to a first transition probability, the second set of symbol sequences corresponding to a reduction of the first set of symbol sequences to exclude ones of the symbol sequences that do not conform to a first element of the composition.

21. A non-transitory computer-readable medium having program code recorded thereon for wireless communication by a wireless communication device, the program code comprising:
code for generating a plurality of information bits;
code for selecting a first energy level based at least in part on the plurality of information bits;
code for determining a composition of an output symbol sequence from among a first set of symbol sequences having the first energy level, including performing a plurality of iterations to identify a plurality of elements of the composition, a quantity of the plurality of iterations being related to a size of a symbol alphabet;
code for determining a plurality of amplitude symbols of the output symbol sequence based at least in part on the composition and the plurality of information bits; and
code for transmitting a wireless packet to at least one receiving device based on the output symbol sequence.

22. The non-transitory computer-readable medium of clause 21, wherein the code for selecting the first energy level comprises:
code for accessing a first plurality of cumulative sequence quantities, each cumulative sequence quantity of the first plurality of cumulative sequence quantities representing a quantity of symbol sequences of a length (n) and having at most a respective energy level;
code for processing the first plurality of cumulative sequence quantities, including selecting the first energy level based at least in part on the plurality of information bits and the first plurality of cumulative sequence quantities.

23. The non-transitory computer-readable medium of any of clauses 21-22, wherein the code for determining the composition comprises code for identifying a first element (kₘ*) of the plurality of elements of the composition including:
code for calculating a first number based at least in part on the plurality of information bits;
code for accessing a plurality of sequence quantities, each one of the sequence quantities defining a set of all sequences having a length n minus km, an energy having been reduced by an amount proportional to km, and a symbol alphabet excluding a first amplitude symbol, and using km as a variable over a range of possible candidates for kₘ*;
code for accessing a plurality of binomial coefficients;
code for computing a plurality of transition probabilities based on the sequence quantities and the binomial coefficients; and
code for determining that a first one of the transition probabilities corresponds to the first number, the first one of the transition probabilities corresponding to the first element of the composition.

24. The non-transitory computer-readable medium of any of clauses 21-23, further comprising:
code for receiving a subsequent wireless packet from a transmitting wireless communication device, the subsequent wireless packet including information having a received symbol sequence and a second energy level and defined by the symbol alphabet; and
code for decoding the subsequent wireless packet, wherein decoding comprises: computing the second energy level, obtaining a second composition of the received symbol sequence by counting symbol occurrences within the subsequent wireless packet; performing a plurality of decoding iterations, each decoding iteration including computing a plurality of transition probabilities and a decoding interval constrained by a prefix composition, and after n of the decoding iterations generating a binary expansion corresponding to a final decoding interval.

25. A wireless communication device configured to encode a plurality (k) of information bits, the wireless communication device comprising:
means for accessing a first plurality of cumulative sequence quantities, each cumulative sequence quantity of the first plurality of cumulative sequence quantities representing a quantity of symbol sequences of a length (n) and having at most a respective energy level;
means for selecting a first energy level based at least in part on the plurality of information bits and the first plurality of cumulative sequence quantities;
means for determining a composition of an output symbol sequence from among a first set of symbol sequences having the first energy level, including;
means for determining a plurality (n) of amplitude symbols of the output symbol sequence based at least in part on the composition and the plurality of information bits; and
means for transmitting a wireless packet to at least one receiving device based on the output symbol sequence.

26. The wireless communication device of clause 25, wherein the means for determining the composition comprises:
means for performing a plurality of iterations to identify a plurality of elements of the composition, a quantity of the plurality of iterations being related to a size of a symbol alphabet.

27. The wireless communication device of clause 26, further comprising means for identifying a first element (kₘ*) of the plurality of elements of the composition, comprising:
means for calculating a first number based at least in part on the plurality of information bits;
means for accessing a plurality of sequence quantities, each one of the sequence quantities defining a set of all sequences having a length n minus kₘ, an energy having been reduced by an amount proportional to kₘ, and a symbol alphabet excluding a first amplitude symbol, and using km as a variable over a range of possible candidates for kₘ*;
means for accessing a plurality of binomial coefficients;
means for computing a plurality of transition probabilities based on the sequence quantities and the binomial coefficients; and
means for determining that a first one of the transition probabilities corresponds to the first number, the first one of the transition probabilities corresponding to the first element of the composition.

28. The wireless communication device of clause 26, wherein a first iteration of the plurality of iterations begins with a first subinterval of an interval and defines a second subinterval, the first subinterval corresponding to the first set of symbol sequences, and the second subinterval corresponding to a second set of symbol sequences, the first subinterval having a length that is proportional to a first transition probability, the second set of symbol sequences corresponding to a reduction of the first set of symbol sequences to exclude ones of the symbol sequences that do not conform to a first element of the composition.

29. The wireless communication device of any of clauses 25-28, wherein the means for selecting the first energy level comprises:
means for performing a first function on the plurality of information bits, the first function generating a first number;
means for computing a set of ratios, wherein each of the ratios is associated with a respective cumulative sequence quantity of the first plurality of cumulative sequence quantities; and
means for determining that the first number corresponds to a first one of the ratios, the first one of the ratios corresponding to the first energy level.

30. The wireless communication device of any of clauses 25-29, further comprising:
means for receiving a subsequent wireless packet from a transmitting wireless communication device, the subsequent wireless packet including information having a received symbol sequence and a second energy level and defined by a symbol alphabet; and
means for decoding the subsequent wireless packet, wherein decoding comprises: computing the second energy level, obtaining a second composition of the received symbol sequence by counting symbol occurrences within the subsequent wireless packet; performing a plurality (n) of decoding iterations, each decoding iteration including computing a plurality of transition probabilities and a decoding interval constrained by a prefix composition, and after n of the decoding iterations generating a binary expansion corresponding to a final decoding interval.

As used herein, “or” is used intended to be interpreted in the inclusive sense, unless otherwise explicitly indicated. For example, “a or b” may include a only, b only, or a combination of a and b. As used herein, a phrase referring to “at least one of” or “one or more of” a list of items refers to any combination of those items, including single members. For example, “at least one of: a, b, or c” is intended to cover the examples of: a only, b only, c only, a combination of a and b, a combination of a and c, a combination of b and c, and a combination of a and b and c.

The various illustrative components, logic, logical blocks, modules, circuits, operations and algorithm processes described in connection with the implementations disclosed herein may be implemented as electronic hardware, firmware, software, or combinations of hardware, firmware or software, including the structures disclosed in this specification and the structural equivalents thereof. The interchangeability of hardware, firmware and software has been described generally, in terms of functionality, and illustrated in the various illustrative components, blocks, modules, circuits and processes described above. Whether such functionality is implemented in hardware, firmware or software depends upon the particular application and design constraints imposed on the overall system.

Various modifications to the implementations described in this disclosure may be readily apparent to persons having ordinary skill in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, various features that are described in this specification in the context of separate implementations also can be implemented in combination in a single implementation. Conversely, various features that are described in the context of a single implementation also can be implemented in multiple implementations separately or in any suitable subcombination. As such, although features may be described above as acting in particular combinations, and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one or more example processes in the form of a flowchart or flow diagram. However, other operations that are not depicted can be incorporated in the example processes that are schematically illustrated. For example, one or more additional operations can be performed before, after, simultaneously, or between any of the illustrated operations. In some circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products.

1. A method for wireless communication by a wireless communication device, the method comprising:
generating a plurality (k) of information bits, wherein k is an integer greater than 1;
performing an encoding operation on the plurality of information bits, the encoding operation including:
accessing a first plurality of cumulative sequence quantities, each cumulative sequence quantity of the first plurality of cumulative sequence quantities representing a quantity of symbol sequences of a length (n) and having at most a respective energy level;
processing the first plurality of cumulative sequence quantities, including selecting a first energy level based at least in part on the plurality of information bits and the first plurality of cumulative sequence quantities;
determining a composition of an output symbol sequence from among a first set of symbol sequences having the first energy level, including performing a plurality of iterations to identify a plurality of elements of the composition, a quantity of the plurality of iterations being related to a size of a symbol alphabet; and
determining the output symbol sequence, including determining a plurality (n) of amplitude symbols of the output symbol sequence based at least in part on the composition and the plurality of information bits, wherein n is an integer greater than 1; and
transmitting a wireless packet to at least one receiving device based on the output symbol sequence.

2. The method of claim 1, wherein each of the amplitude symbols is selected from the symbol alphabet having size m, the symbol alphabet defining a set of different amplitude symbols, wherein m is an integer greater than 1.

3. The method of claim 1, wherein selecting the first energy level comprises:
performing a first function on the plurality of information bits, the first function generating a first number;
computing a set of ratios, wherein each of the ratios is associated with a respective one of the first plurality of cumulative sequence quantities; and
determining that the first number corresponds to a first one of the ratios, the first one of the ratios corresponding to the first energy level.

4. The method of claim 3, wherein the first number comprises a dyadic number.

5. The method of claim 1, further comprising:
receiving a subsequent wireless packet from a transmitting wireless communication device, the subsequent wireless packet including information having a received symbol sequence of n amplitude symbols and a second energy level and defined by the symbol alphabet; and
decoding the subsequent wireless packet, wherein decoding comprises: computing the second energy level, obtaining a second composition of the received symbol sequence by counting symbol occurrences within the subsequent wireless packet; performing a plurality (n) of decoding iterations, each decoding iteration including computing a plurality of transition probabilities and a decoding interval constrained by a prefix composition, and after n of the decoding iterations generating a binary expansion corresponding to a final decoding interval.

6. The method of claim 1, wherein identifying a first element (kₘ*) of the plurality of elements of the composition comprises:
calculating a first number based at least in part on the plurality of information bits;
accessing a plurality of sequence quantities, each one of the sequence quantities defining a set of all sequences having a length n minus km, an energy having been reduced by an amount proportional to kₘ, and a symbol alphabet excluding a first amplitude symbol, and using kₘ as a variable over a range of possible candidates for kₘ*;
accessing a plurality of binomial coefficients;
computing a plurality of transition probabilities based on the sequence quantities and the binomial coefficients; and
determining that a first one of the transition probabilities corresponds to the first number, the first one of the transition probabilities corresponding to the first element (kₘ*) of the plurality of elements of the composition.

7. The method of claim 6, further comprising:
generating a residual energy value in accordance with determining the first element (kₘ*) of the plurality of elements of the composition.

8. The method of claim 6, further comprising:
generating a residual length value in accordance with determining the first element (kₘ*) of the plurality of elements of the composition.

9. The method of claim 6, further comprising:
scaling the first number in accordance with determining the first element (kₘ*) of the plurality of elements of the composition.

10. The method of claim 6, further comprising:
performing a second iteration to determine a second element (kₘ₋₁*) of the plurality of elements of the composition, including:
generating a residual energy value and a residual length value in accordance with determining the first element (kₘ*) of the plurality of elements of the composition;
calculating a second number based on the plurality of information bits;
accessing a second plurality of sequence quantities defining a set of all sequences having a second length of the residual length value minus kₘ₋₁, a second energy equal to the residual energy value minus a second amount proportional to kₘ₋₁, and a second symbol alphabet excluding the first amplitude symbol and a second amplitude symbol, using kₘ₋₁ as a variable over a range of possible candidates for kₘ₋₁*;
accessing a second plurality of binomial coefficients;
computing a second plurality of transition probabilities based on the second plurality of sequence quantities and the second plurality of binomial coefficients; and
determining that a second one of the second plurality of transition probabilities corresponds to the second number, the second one of the transition probabilities corresponding to the second element (kₘ₋₁*) of the plurality of elements of the composition.

11. The method of claim 1, wherein a first iteration of the plurality of iterations begins with a first subinterval of a first interval and defines a second subinterval, the first subinterval corresponding to the first set of symbol sequences, and the second subinterval corresponding to a second set of symbol sequences, the first subinterval having a length that is proportional to a first transition probability, the second set of symbol sequences corresponding to a reduction of the first set of symbol sequences to exclude ones of the symbol sequences that do not conform to a first element of the composition.

12. The method of claim 11, further comprising:
scaling a first number according to the reduction of the first set of symbol sequences, wherein the first number is computed using the plurality of information bits.

13. The method of claim 11, further comprising:
scaling the first subinterval to be a same size as the first interval.

14. The method of claim 1, wherein the encoding operation and the transmitting is performed by a user equipment (UE) or a wireless base station (BS).

15. (canceled)

16. A wireless communication device comprising:
at least one modem;
at least one processor communicatively coupled with the at least one modem; and
at least one memory communicatively coupled with the at least one processor and storing processor-readable code that, when executed by the at least one processor in conjunction with the at least one modem, is configured to:
generate a plurality of information bits;
access a first plurality of cumulative sequence quantities, each cumulative sequence quantity of the first plurality of cumulative sequence quantities representing a quantity of symbol sequences of a length (n) and having at most a respective energy level;
process the first plurality of cumulative sequence quantities, including selecting a first energy level based at least in part on the plurality of information bits and the first plurality of cumulative sequence quantities;
determine a composition of an output symbol sequence from among a first set of symbol sequences having the first energy level, including performing a plurality of iterations to identify a plurality of elements of the composition, a quantity of the plurality of iterations being related to a size of a symbol alphabet; and
determine the output symbol sequence, including determining a plurality (n) of amplitude symbols of the output symbol sequence based at least in part on the composition and the plurality of information bits; and
transmit a wireless packet to at least one receiving device based on the output symbol sequence.

17. The wireless communication device of claim 16, wherein the processor-readable code to cause the wireless communication device to select the first energy level comprises processor-readable code to cause the wireless communication device to:
perform a first function on the plurality of information bits, the first function generating a first number;
compute a set of ratios, wherein each of the ratios is associated with a respective cumulative sequence quantity of the first plurality of cumulative sequence quantities; and
determine that the first number corresponds to a first one of the ratios, the first one of the ratios corresponding to the first energy level.

18. The wireless communication device of claim 16, wherein the at least one processor in conjunction with the at least one modem, is further configured to:
receive a subsequent wireless packet from a transmitting wireless communication device, the subsequent wireless packet including information having a received symbol sequence and a second energy level and defined by the symbol alphabet; and
decode the subsequent wireless packet, wherein decoding comprises: computing the second energy level, obtaining a second composition of the received symbol sequence by counting symbol occurrences within the subsequent wireless packet; performing a plurality (n) of decoding iterations, each decoding iteration including computing a plurality of transition probabilities and a decoding interval constrained by a prefix composition, and after n of the decoding iterations generating a binary expansion corresponding to a final decoding interval.

19. The wireless communication device of claim 16, wherein the at least one processor in conjunction with the at least one modem, is further configured to:
identify a first element (kₘ*) of the plurality of elements of the composition, including calculating a first number based at least in part on the plurality of information bits;
access a plurality of sequence quantities, each one of the sequence quantities defining a set of all sequences having a length n minus kₘ, an energy having been reduced by an amount proportional to km, and a symbol alphabet excluding a first amplitude symbol, and using km as a variable over a range of possible candidates for kₘ*;
access a plurality of binomial coefficients;
compute a plurality of transition probabilities based on the sequence quantities and the binomial coefficients; and
determine that a first one of the transition probabilities corresponds to the first number, the first one of the transition probabilities corresponding to the first element (kₘ*) of the plurality of elements of the composition.

20. The wireless communication device of claim 16, wherein a first iteration of the plurality of iterations begins with a first subinterval of a first interval and defines a second subinterval, the first subinterval corresponding to the first set of symbol sequences, and the second subinterval corresponding to a second set of symbol sequences, the first subinterval having a length that is proportional to a first transition probability, the second set of symbol sequences corresponding to a reduction of the first set of symbol sequences to exclude ones of the symbol sequences that do not conform to a first element of the composition.

21. (canceled)

22. (canceled)

23. (canceled)

24. (canceled)

25. A wireless communication device configured to encode a plurality (k) of information bits, the wireless communication device comprising:
means for accessing a first plurality of cumulative sequence quantities, each cumulative sequence quantity of the first plurality of cumulative sequence quantities representing a quantity of symbol sequences of a length (n) and having at most a respective energy level;
means for selecting a first energy level based at least in part on the plurality of information bits and the first plurality of cumulative sequence quantities;
means for determining a composition of an output symbol sequence from among a first set of symbol sequences having the first energy level, including;
means for determining a plurality (n) of amplitude symbols of the output symbol sequence based at least in part on the composition and the plurality of information bits; and
means for transmitting a wireless packet to at least one receiving device based on the output symbol sequence.

26. (canceled)

27. (canceled)

28. (canceled)

29. (canceled)

30. (canceled)
